(19) United States
(12) Patent Application Publication
(10) Pub. No.: US 2026/0176293 A1
(43) Pub. Date: Jun. 25, 2026

(54) ORGANOMETALLIC COMPOUND, RESIST COMPOSITION INCLUDING THE SAME, AND PATTERN FORMATION METHOD USING THE RESIST COMPOSITION

(71) Applicant: Samsung Electronics Co., Ltd., Suwon-si (KR)

(72) Inventors: Sunghyun HAN, Suwon-si (KR); Haengdeog KOH, Suwon-si (KR); Sunyoung LEE, Suwon-si (KR); Jiyoun LEE, Suwon-si (KR); Changheon LEE, Suwon-si (KR); Jinwon JEON, Suwon-si (KR); Jungha CHAE, Suwon-si (KR)

(73) Assignee: Samsung Electronics Co., Ltd., Suwon-si (KR)

(21) Appl. No.: 19/216,177

(22) Filed: May 22, 2025

(30) Foreign Application Priority Data
Dec. 20, 2024 (KR) 10-2024-0193318

(51) Int. Cl. C07F 7/22; G03F 7/004; G03F 7/16

(52) U.S. Cl. CPC C07F 7/2224; G03F 7/0042; G03F 7/168

(57) ABSTRACT

Provided are an organometallic compound represented by Formula 1, a resist composition including the same, and a pattern formation method using the resist composition:

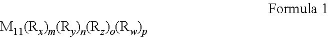

Wherein
descriptions of M₁₁, Rₓ, R_{y}, R_{z}, R_{w}, n, m, o, and p in Formula 1 are provided in the specification.

### CROSS-REFERENCE TO RELATED APPLICATION

This application is based on and claims priority under 35 U.S.C. § 119 to Korean Patent Application No. 10-2024-0193318, filed on Dec. 20, 2024, in the Korean Intellectual Property Office, the disclosure of which is incorporated by reference herein in its entirety.

### BACKGROUND

### 1. Field

The inventive concepts relate to organometallic compounds, resist compositions including the same, and pattern formation methods using the resist compositions.

### 2. Description of the Related Art

During manufacturing of semiconductors, resists having physical properties that change in response to light are being used to form fine patterns. Among the resists, chemically amplified resists have been widely used. A chemically amplified resist enables patterning by allowing acids, formed by a reaction between light (e.g., incident light having a particular intensity and/or wavelength) and photoacid generators, to react again with a base resin, changing the solubility of the base resin in a developer.

### SUMMARY

Provided are an organometallic compound of which physical properties change even with low-dose exposure and which provides a pattern with improved resolution and has improved solution stability, a resist composition including the same, and a pattern formation method using the resist composition. Such a resist composition may have a composition which has improved storage stability, wherein the resist composition is configured to change one or more physical properties even by exposure to incident light (e.g., high-energy rays), in order to overcome limitations of chemically amplified resists which may cause a formed acid to diffuse to an unexposed region, such that the resist composition reduces, minimizes, or prevents the likelihood of a reduction in uniformity of patterns or an increase in surface roughness based on avoiding such formed acid diffusion, while simultaneously providing improved resist composition chemical stability (and thereby reduced, minimized, or prevented risk of chemical deterioration) in normal usage environments at room temperature and/or while simultaneously changing physical properties even by exposure to a small amount (e.g., small intensity) of incident light (e.g., high-energy rays).

Additional aspects will be set forth in part in the description which follows and, in part, will be apparent from the description, or may be learned by practice of the presented embodiments of the inventive concepts.

According to some example embodiments of the inventive concepts, provided is an organometallic compound represented by Formula 1:

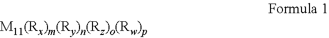

wherein, in Formula 1,
M₁₁ may be indium (In), tin (Sn), antimony (Sb), tellurium (Te), thallium (Tl), lead (Pb), bismuth (Bi), or polonium (Po),
Rₓ may be *—X₁₁—Y₁₁, R_{y} may be *—X₁₂—Y₁₂, and R_{z} may be *—X₁₃—Y₁₃,
R_{w} may be *-(L₁)ₐ₁-(R₁)_{b1},
n may be an integer from 1 to 4, m may be an integer from 1 to 4, o may be an integer from 0 to 4, and p may be an integer from 1 to 4,
m+n+o+p may be 6 or less,
Rₓ and R_{y} may be different from each other,
Formula 1 may optionally include a plurality of Rₓ based on m being greater than 1, the plurality of Rₓ identical to each other,
Formula 1 may optionally include a plurality of R_{y} based on n being greater than 1, the plurality of R_{y} identical to each other,
Formula 1 may optionally include a plurality of R_{z} based on o being greater than 1, the plurality of R_{z} identical to or different from each other,
Formula 1 may optionally include a plurality of R_{w} based on p being greater than 1, the plurality of R_{w} identical to or different from each other,
X₁₁ to X₁₃ may each independently be O, OC(═O), C(═O)O, OS(═O), S(═O)O, OS(═O)₂, S(═O)₂O, S, SC(═O), or C(═O)S,
Y₁₁ to Y₁₃ may each independently be hydrogen, deuterium, or a linear, branched, or cyclic C₁-C₃₀ monovalent hydrocarbon group optionally including a heteroatom,
L₁ may be a linear, branched, or cyclic C₁-C₃₀ divalent hydrocarbon group optionally including a heteroatom,
a1 may be an integer from 0 to 4,
R₁ may be a linear, branched, or cyclic C₁-C₃₀ monovalent hydrocarbon group optionally including a heteroatom,
b1 may be an integer from 1 to 4, wherein Formula 1 may optionally include a plurality of R₁ based on b1 being greater than 1, two adjacent groups among the plurality of R₁ optionally bonded to each other to form a ring, and
* indicates a binding site to a neighboring atom.

In Formula 1, M₁₁ may be Sn, Sb, Te, or Bi.

In Formula 1, n may be 1 or 2, m may be 1 or 2, o may be an integer from 0 to 2, and p may be 1 or 2.

In Formula 1, n is 1 or 2, m may be 1 or 2, o may be an integer from 0 to 2, p may be 1 or 2, m+n+o+p may be 4, and M₁₁ may be Sn.

In Formula 1, a first bond between M₁₁ and Rₓ may be an M₁₁-oxygen single bond or an M₁₁-sulfur single bond, a second bond between M₁₁ and R_{y} may be an M₁₁-oxygen single bond or an M₁₁-sulfur single bond, a third bond between M₁₁ and R_{z} may be an M₁₁-oxygen single bond or an M₁₁-sulfur single bond, and a fourth bond between M₁₁ and R_{w} may be an M₁₁-carbon single bond.

In Formula 1, a difference in molecular weight between Rₓ and R_{y} may be about 40 g/mol or more.

In Formula 1, a light sensitivity of Rₓ may be greater than a light sensitivity of R_{y}, and a moisture sensitivity of Rₓ may be greater than a moisture sensitivity of R_{y}.

In Formula 1, X₁₁ to X₁₃ may each independently be O, OC(═O), C(═O)O, S, SC(═O), or C(═O)S, and Y₁₁ to Y₁₃ may each independently be hydrogen, deuterium, a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group.

In Formula 1, L₁ may be a single bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group, and R₁ may be a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, a substituted or unsubstituted C₇-C₃₀ arylalkyl group, a substituted or unsubstituted C₁-C₃₀ heteroaryl group, or a substituted or unsubstituted C₂-C₃₀ heteroarylalkyl group.

The organometallic compound represented by Formula 1 may be represented by one of Formulae 1-1 or 1-2:

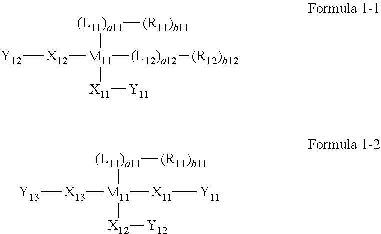

wherein, in Formulae 1-1 and 1-2,
M₁₁ may be indium (In), tin (Sn), antimony (Sb), tellurium (Te), thallium (Tl), lead (Pb), bismuth (Bi), or polonium (Po),
X₁₁ to X₁₃ may each independently be O, OC(═O), C(═O)O, OS(═O), S(═O)O, OS(═O)₂, S(═O)₂O, S, SC(═O), or C(═O)S,
Y₁₁ to Y₁₃ may each independently be hydrogen, deuterium, or a linear, branched, or cyclic C₁-C₃₀ monovalent hydrocarbon group optionally including a heteroatom,
L₁ and L₁₂ may each independently be a linear, branched, or cyclic C₁-C₃₀ divalent hydrocarbon group optionally including a heteroatom,
a11 and a12 may each independently be an integer from 0 to 4,
R₁₁ and R₁₂ are each independently a linear, branched, or cyclic C₁-C₃₀ monovalent hydrocarbon group optionally including a heteroatom, and
b11 and b12 may each independently be is an integer from 1 to 4, wherein
Formulae 1-1 and 1-2 may optionally include a plurality of R₁₁ based on b11 being greater than 1, two adjacent groups among the plurality of R₁₁ optionally bonded to each other to form a ring, and
Formulae 1-1 and 1-2 may optionally include a plurality of R₁₂ based on b12 being greater than 1, two adjacent groups among the plurality of R₁₂ optionally bonded to each other to form a ring.

The organometallic compound represented by Formula 1 may be selected from Group I:

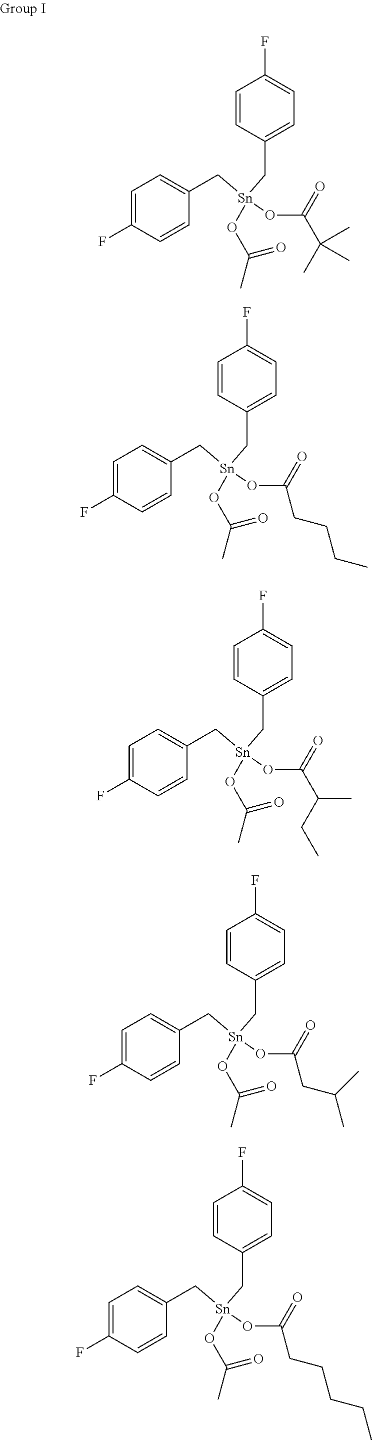

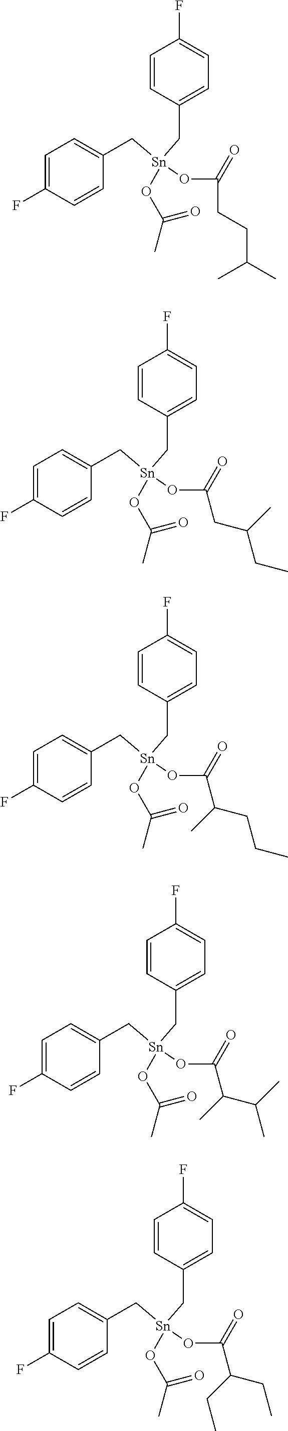

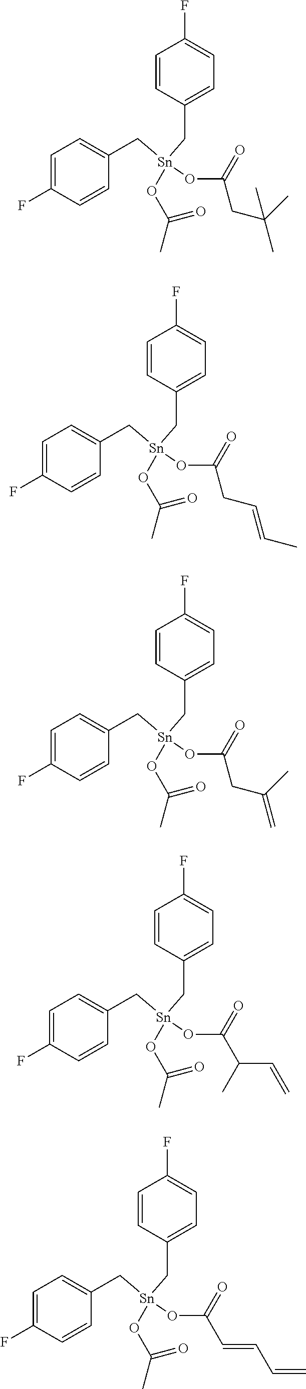

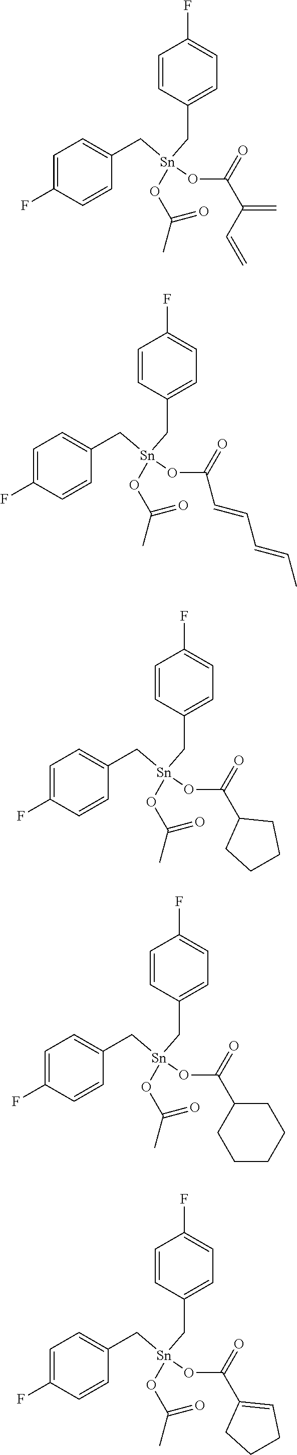

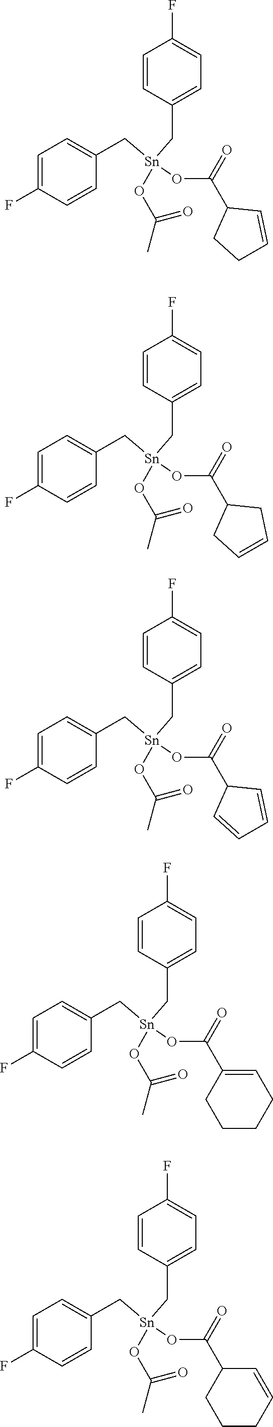

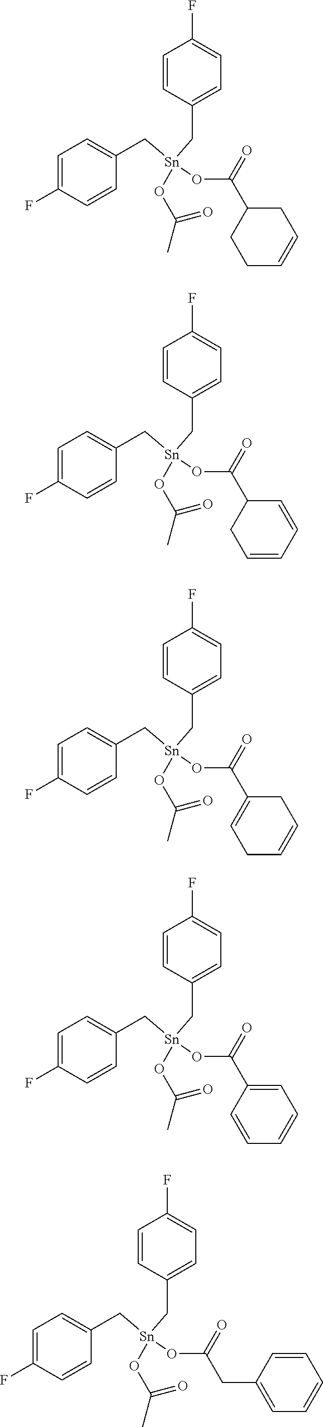 [SMILES: CC(=O)[O][Sn]([CH2]c1ccc(F)cc1)([CH2]c1ccc(F)cc1)[O]C(=O)C1CC=CCC1 ; CC(=O)[O][Sn]([CH2]c1ccc(F)cc1)([CH2]c1ccc(F)cc1)[O]C(=O)C1C=CC=CC1 ; CC(=O)[O][Sn]([CH2]c1ccc(F)cc1)([CH2]c1ccc(F)cc1)[O]C(=O)C1=CCC=CC1 ; CC(=O)[O][Sn]([CH2]c1ccc(F)cc1)([CH2]c1ccc(F)cc1)[O]C(=O)c1ccccc1 ; CC(=O)[O][Sn]([CH2]c1ccc(F)cc1)([CH2]c1ccc(F)cc1)[O]C(=O)Cc1ccccc1]

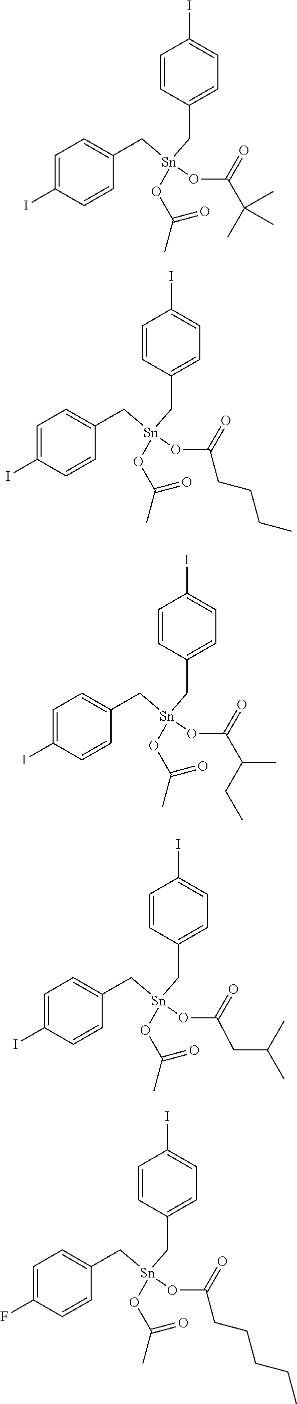

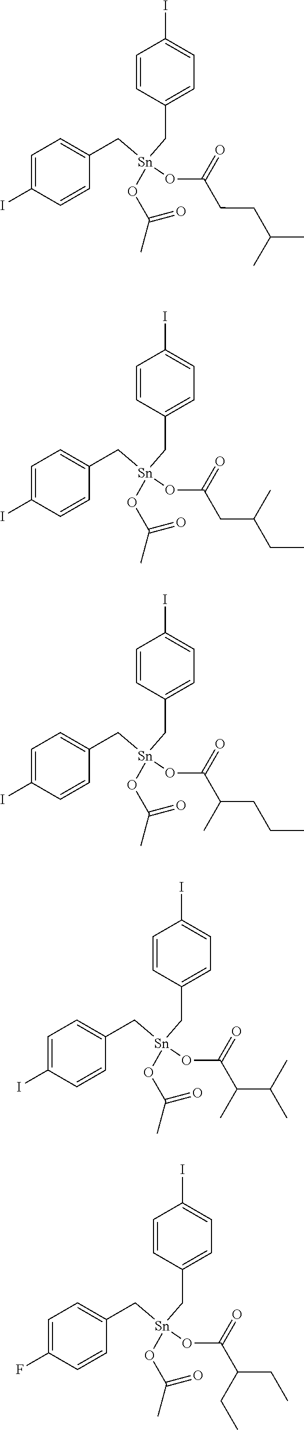

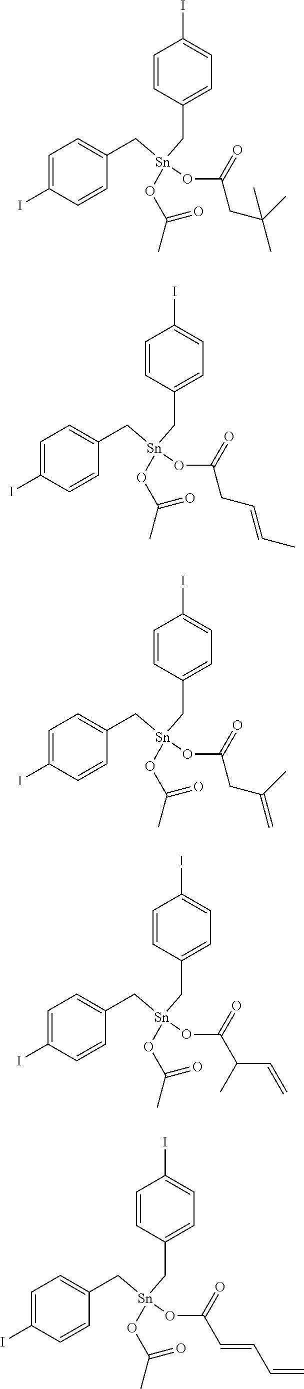

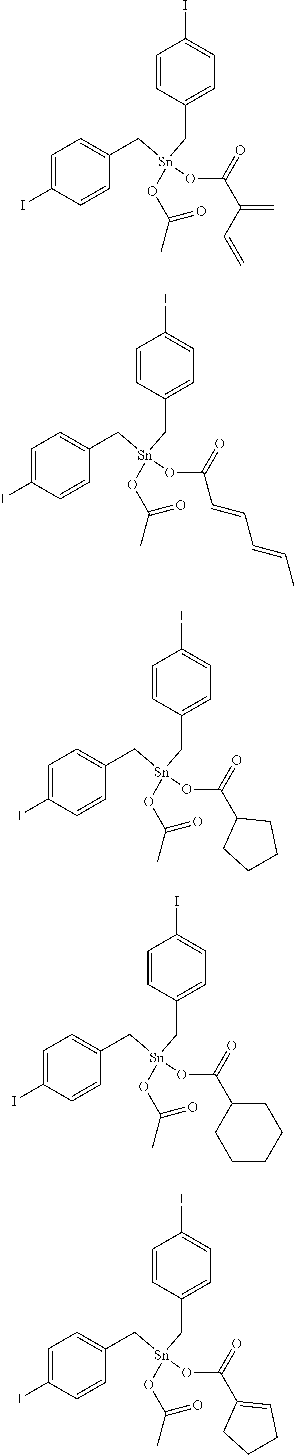

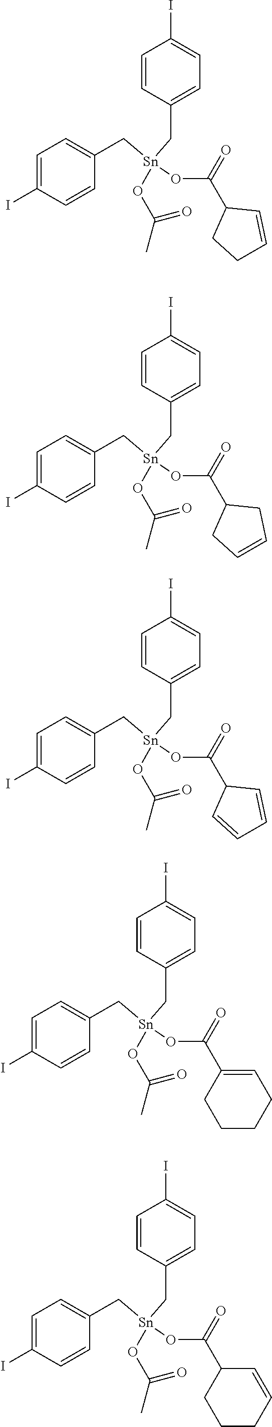

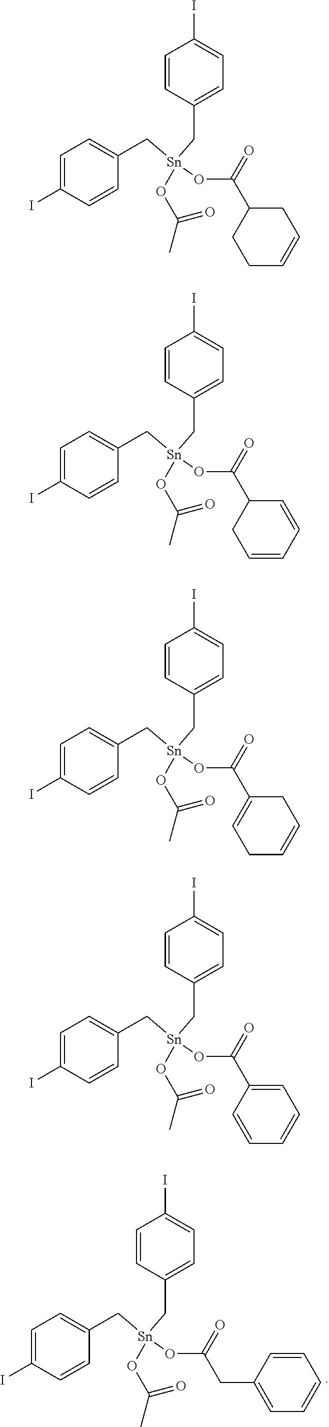 [SMILES: CC(=O)[O][Sn]([CH2]c1ccc(I)cc1)([CH2]c1ccc(I)cc1)[O]C(=O)C1CC=CCC1 ; CC(=O)[O][Sn]([CH2]c1ccc(I)cc1)([CH2]c1ccc(I)cc1)[O]C(=O)C1C=CC=CC1 ; CC(=O)[O][Sn]([CH2]c1ccc(I)cc1)([CH2]c1ccc(I)cc1)[O]C(=O)C1=CCC=CC1 ; CC(=O)[O][Sn]([CH2]c1ccc(I)cc1)([CH2]c1ccc(I)cc1)[O]C(=O)c1ccccc1 ; CC(=O)[O][Sn]([CH2]c1ccc(I)cc1)([CH2]c1ccc(I)cc1)[O]C(=O)Cc1ccccc1]

According to some example embodiments, a resist composition may include a first organometallic compound, the first organometallic compound being the organometallic compound.

The resist composition may further include at least one of a second organometallic compound represented by Formula 2-1 or a third organometallic compound represented by Formula 2-2, the first organometallic compound and the second organometallic compound may be different from each other, the first organometallic compound and the third organometallic compound may be different from each other, and the second organometallic compound and the third organometallic compound are different from each other:

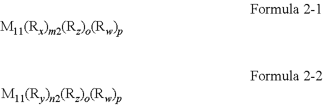

wherein, in Formulae 2-1 and 2-2,
M₁₁ may be In, Sn, Sb, Te, Tl, Pb, Bi, or Po,
Rₓ may be *—X₁₁—Y₁₁,
R_{y} may be *—X₁₂—Y₁₂,
R_{z} may be *—X₁₃—Y₁₃,
R_{w} may be *-(L₁)ₐ₁-(R₁)_{b1},
m2 may be an integer from 2 to 4,
n2 may be an integer from 2 to 4,
o may be an integer from 0 to 4,
p may be an integer from 1 to 4,
m2+o+p may be 6 or less,
n2+o+p may be 6 or less,
Formula 2-1 may optionally include a plurality of Rₓ based on m2 being greater than 1, the plurality of Rₓ identical to each other,
Formula 2-2 may optionally include a plurality of R_{y} based on n2 being greater than 1, the plurality of R_{y} identical to each other,
Formulae 2-1 and 2-2 may each optionally include a plurality of R_{z} based on o being greater than 1, the plurality of R_{z} identical to or different from each other,
Formulae 2-1 and 2-2 may each optionally include a plurality of R_{w} based on p being greater than 1, the plurality of R_{w} identical to or different from each other,
X₁₁ to X₁₃ may each independently be O, OC(═O), C(═O)O, OS(═O), S(═O)O, OS(═O)₂, S(═O)₂O, S, SC(═O), or C(═O)S,
Y₁₁ to Y₁₃ may each independently be hydrogen, deuterium, or a linear, branched, or cyclic C₁-C₃₀ monovalent hydrocarbon group optionally including a heteroatom,
L₁ may be a linear, branched, or cyclic C₁-C₃₀ divalent hydrocarbon group optionally including a heteroatom,
a1 may be an integer from 0 to 4,
R₁ may be a linear, branched, or cyclic C₁-C₃₀ monovalent hydrocarbon group optionally including a heteroatom,
b1 may be an integer from 1 to 4, wherein Formulae 2-1 and 2-2 each optionally include a plurality of R₁ based on b1 being greater than 1, two adjacent groups among the plurality of R₁ optionally bonded to each other to form a ring, and
* indicates a binding site to a neighboring atom of Formula 2-1 or Formula 2-2.

The resist composition may be substantially free of any photoacid generator.

The resist composition may be substantially free of any compounds having a molecular weight of about 1,000 or more.

The resist composition may further comprise an organic solvent.

The organic solvent may be a polar aprotic solvent.

According to some example embodiments, a pattern formation method may include: applying the resist composition onto a substrate, to form a resist film; exposing at least a portion of the resist film to high-energy rays to form an exposed resist film; and developing the exposed resist film based on using a developer.

The exposing may be performed based on irradiating at least one of ultraviolet rays, deep ultraviolet (DUV) rays, extreme ultraviolet (EUV) rays, X-rays, γ-rays, electron beams (EBs), or α-rays.

Based on the exposing at least the portion of the resist film, the exposed resist film may include an exposed portion and an unexposed portion, and the developing the exposed resist film may include removing the unexposed portion.

According to some example embodiments of the inventive concepts, a resist composition includes the above-described organometallic compound.

According to some example embodiments of the inventive concepts, a pattern formation method includes applying the above-described resist composition onto a substrate to form a resist film, exposing at least a portion of the resist film to high-energy rays, and developing the exposed resist film by using a developer.

### BRIEF DESCRIPTION OF THE DRAWINGS

The above and other aspects, features, and advantages of certain embodiments of the inventive concepts will be more apparent from the following description taken in conjunction with the accompanying drawings, in which:

FIG. 1 is a flowchart illustrating a pattern formation method according to some example embodiments;

FIGS. 2A, 2B, and 2C are side cross-sectional views illustrating a pattern formation method according to some example embodiments;

FIGS. 3A, 3B, 3C, 3D, and 3E are side cross-sectional views illustrating a method of forming a patterned structure, according to some example embodiments;

FIGS. 4A, 4B, 4C, 4D, and 4E are side cross-sectional views illustrating a method of forming a semiconductor device according to some example embodiments;

FIGS. 5A, 5B, 5C, and 5D are drawings illustrating changes in film thickness measured after storage of each of RM1, RM2, SM1, SM2, and SM3 for a particular (or, alternatively, predetermined) period of time, according to some example embodiments; and

FIGS. 6A, 6B, and 6C are drawings illustrating changes in film thickness after development according to dose, which were measured after storage of each of RM1, SM1, and SM2 for a particular (or, alternatively, predetermined) period of time, according to some example embodiments.

### DETAILED DESCRIPTION

Reference will now be made in detail to example embodiments, some of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Because the inventive concepts may have diverse modified embodiments, some example embodiments are illustrated in the drawings and are described in the detailed description. However, it should be understood that this is not intended to limit the inventive concepts to specific embodiments, and includes all modifications, equivalents, and substitutes included in the spirit and scope of the inventive concepts. In describing the inventive concepts, when it is determined that the specific description of the known related art obscures the gist of the inventive concepts, the detailed description thereof will be omitted.

The use of the term “the” and similar demonstratives may correspond to both the singular and the plural. Operations constituting methods may be performed in any suitable order unless otherwise indicated herein or otherwise clearly contradicted by context, and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

Regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

When a first element is described herein to be “substantially free” of a second one or more elements, it is intended that the first element may contain 3 wt % or less of the second one or more elements (e.g., 0.01 wt % to 3 wt %, 0.1 wt % to 3 wt %, 1 wt % to 3 wt %, etc.). Further, regardless of whether a statement that a first element is “free” of a second one or more elements is modified as “substantially” free, it will be understood that a first element described to be “free” of a second one or more elements should be construed as containing between 0 wt % to 3 wt %, of the second one or more elements, for example not including any of the second one or more elements (0 wt %) or including 3 wt % or less of the one or more elements (e.g., 0.01 wt % to 3 wt %, 0.1 wt % to 3 wt %, 1 wt % to 3 wt %, etc.).

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

It will be understood that, although the terms “first,” “second,” and “third” may be used herein to describe various elements, these elements should not be limited by these terms. These terms are only used to distinguish one element from another element and not used to limit order or types of elements.

In the present specification, when a portion of a layer, film, region, plate, or the like is described as being “on” or “above” another portion, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Hereinafter, unless explicitly described to the contrary, it is to be understood that the terms such as “including” or “having” are intended to indicate the existence of the features, numbers, steps, operations, components, parts, ingredients, materials, or combinations thereof disclosed in the specification and are not intended to preclude the possibility that one or more other features, numbers, steps, operations, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

As used herein, “Cₓ-C_{y}” or “Cₓ to C_{y}” means that a number (e.g., quantity) of carbons constituting a substituent is x to y, wherein x and y may each be any natural number. For example, “C₁-C₆” and “C₁ to C₆” means that a number of carbons constituting the substituent is 1 to 6, and “C₆-C₂₀” and C₆ to C₂₀” means that a number of carbons constituting the substituent is 6 to 20.

The term “monovalent hydrocarbon group” used herein refers to a monovalent residue derived from an organic compound including carbon and hydrogen or a derivative thereof, and specific examples thereof may include: a linear or branched alkyl group (e.g., a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); a monovalent saturated cycloaliphatic hydrocarbon group (a cycloalkyl group) (e.g., a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group); a monovalent unsaturated aliphatic hydrocarbon group (an alkenyl group or an alkynyl group) (e.g., an allyl group); a monovalent unsaturated cycloaliphatic hydrocarbon group (a cycloalkenyl group) (e.g., a 3-cyclohexenyl group); an aryl group (e.g., a phenyl group, a 1-naphthyl group, and a 2-naphthyl group); an arylalkyl group (e.g., a benzyl group and a diphenylmethyl group); a heteroatom-containing monovalent hydrocarbon group (e.g., a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group), or any combination thereof. In addition, in these groups, some hydrogen atoms may be substituted by a moiety including a heteroatom (e.g., one or more heteroatoms), such as oxygen, sulfur, nitrogen, or a halogen atom, or some carbon atoms may be substituted by a moiety including a heteroatom (e.g., one or more heteroatoms), such as oxygen, sulfur, or nitrogen, so that these groups may include a hydroxyl group, a cyano group, a carbonyl group, a carboxyl group, an ether bond, an ester bond, a sulfonate bond, a carbonate, a lactone ring, a sultone ring, a carboxylic anhydride moiety, or a haloalkyl moiety.

The term “divalent hydrocarbon group” as used herein is a divalent residue and means that any one hydrogen atom of the monovalent hydrocarbon group is replaced with a binding site to a neighboring atom. The divalent hydrocarbon group may include, for example, a linear or branched alkylene group, a cycloalkylene group, an alkenylene group, an alkynylene group, a cycloalkylene group, an arylene group, a group in which some carbon atoms thereof are replaced with a heteroatom (e.g., one or more heteroatoms), and the like.

The term “alkyl group” as used herein refers to a linear or branched saturated aliphatic hydrocarbon monovalent group, and specific examples thereof may include a methyl group, an ethyl group, a propyl group, an isobutyl group, a sec-butyl group, a tert-butyl group, a pentyl group, an iso-amyl group, a hexyl group, and the like. The term “alkylene group” as used herein refers to a linear or branched saturated aliphatic hydrocarbon divalent group, and specific examples thereof may include a methylene group, an ethylene group, a propylene group, a butylene group, an isobutylene group, and the like.

The term “halogenated alkyl group” as used herein refers to a group in which one or more substituents of an alkyl group are substituted with a halogen, and specific examples thereof may include CF₃ and the like. Here, the halogen may be F, Cl, Br, or I.

The term “alkoxy group” as used herein refers to a monovalent group having a Formula of —OA₁₀₁, wherein A₁₀₁ may be an alkyl group. Specific examples thereof may include a methoxy group, an ethoxy group, an isopropyloxy group, and the like.

The term “alkylthio group” as used herein refers to a monovalent group having a Formula of —SA₁₀₁, wherein A₁₀₁ may be an alkyl group.

The term “halogenated alkoxy group” as used herein refers to a group in which one or more hydrogen atoms of an alkoxy group are substituted with a halogen, and specific examples thereof may include —OCF₃ and the like.

The term “halogenated alkylthio group” as used herein refers to a group in which one or more hydrogen atoms of an alkylthio group are substituted with a halogen, and specific examples thereof may include —SCF₃ and the like.

The term “cycloalkyl group” as used herein refers to a monovalent saturated hydrocarbon cyclic group, and specific examples thereof may include monocyclic groups such as a cyclopropyl group, a cyclobutyl group, a cyclopentyl group, a cyclohexyl group, and a cycloheptyl group, and polycyclic condensed cyclic groups such as a norbornyl group and an adamantyl group. The term “cycloalkylene group” as used herein refers to a divalent saturated hydrocarbon cyclic group, and specific examples thereof may include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

The term “cycloalkoxy group” as used herein refers to a monovalent group having a Formula of —OA₁₀₂, wherein A₁₀₂ may be a cycloalkyl group. Specific examples thereof may include a cyclopropoxy group, a cyclobutoxy group, and the like.

The term “cycloalkylthio group” as used herein refers to a monovalent group having a Formula of —SA₁₀₂, wherein A₁₀₂ may be a cycloalkyl group.

The term “heterocycloalkyl group” as used herein may be a group in which some carbon atoms of the cycloalkyl group are replaced by a moiety including a heteroatom (e.g., one or more heteroatoms), such as oxygen, sulfur, or nitrogen. The heterocycloalkyl group may include an ether bond, an ester bond, a sulfonate bond, carbonate, a lactone ring, a sultone ring, or a carboxylic anhydride moiety. The term “heterocycloalkylene group” as used herein refers to a group in which some carbon atoms of the cycloalkylene group are replaced by a moiety including a heteroatom (e.g., one or more heteroatoms), such as oxygen, sulfur, or nitrogen.

The term “heterocycloalkoxy group” as used herein refers to a monovalent group having a Formula of —OA₁₀₃, wherein A₁₀₃ may be a heterocycloalkyl group.

The term “alkenyl group” as used herein refers to a linear or branched unsaturated aliphatic hydrocarbon monovalent group including one or more carbon-carbon double bonds. The term “alkenylene group” as used herein refers to a linear or branched unsaturated aliphatic hydrocarbon divalent group including one or more carbon-carbon double bonds.

The term “alkenyloxy group” as used herein refers to a monovalent group having a formula of —OA₁₀₄, wherein A₁₀₄ is an alkenyl group.

The term “cycloalkenyl group” as used herein refers to a monovalent unsaturated hydrocarbon cyclic group including one or more carbon-carbon double bonds. The term “cycloalkenylene group” as used herein refers to a divalent unsaturated hydrocarbon cyclic group including one or more carbon-carbon double bonds.

The term “cycloalkenyloxy group” as used herein refers to a monovalent group having a formula of —OA₁₀₅, where A₁₀₅ is a cycloalkenyl group.

The term “heterocycloalkenyl group” as used herein refers to a group in which some carbon atoms of the cycloalkenylene group are replaced by a moiety including a heteroatom (e.g., one or more heteroatoms), such as oxygen, sulfur, or nitrogen. The term “heterocycloalkenylene group” as used herein refers to a group in which some carbon atoms of the cycloalkenylene group are replaced by a moiety including a heteroatom (e.g., one or more heteroatoms), such as oxygen, sulfur, or nitrogen.

The term “heterocycloalkenyloxy group” as used herein refers to a monovalent group having a formula of —OA₁₀₆, wherein A₁₀₆ is a heterocycloalkenyl group.

The term “alkynyl group” as used herein refers to a linear or branched unsaturated aliphatic hydrocarbon monovalent group including one or more carbon-carbon triple bonds.

The term “alkynyloxy group” as used herein refers to a monovalent group having a formula of —OA₁₀₇, wherein A₁₀₇ is an alkynyl group.

The term “aryl group” as used herein refers to a monovalent group having a carbocyclic aromatic system, and specific examples thereof may include a phenyl group, a naphthyl group, an anthracenyl group, a phenanthrenyl group, a pyrenyl group, a chrysenyl group, and the like. The term “arylene group” as used herein refers to a divalent group having a carbocyclic aromatic system.

The term “heteroaryl group” as used herein refers to a monovalent group having a heterocyclic aromatic system, and specific examples thereof may include a pyridinyl group, a pyrimidinyl group, a pyrazinyl group, and the like. The term “heteroarylene group” as used herein refers to a divalent group having a heterocyclic aromatic system.

The term “substituent” as used herein may include: deuterium, a halogen atom, a hydroxyl group, a cyano group, a nitro group, a carbonyl group, a carboxylate group, an amino group, an ether moiety, an ester moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group;
a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₅-C₂₀ cycloalkoxy group, a C₅-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group, each substituted with deuterium, a halogen atom, a hydroxyl group, a cyano group, a nitro group, a carbonyl group, a carboxylate group, amino group, an ether moiety, an ester moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₅-C₂₀ cycloalkyl group, a C₅-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, or any combination thereof.

As used herein, when a definition is not otherwise provided, “aromatic ring” refers to a functional group in which all atoms in the cyclic functional group have a p-orbital, and wherein these p-orbitals are conjugated.

Hereinafter, some example embodiments will be described in detail with reference to the accompanying drawings, wherein like reference numerals denote substantially the same or corresponding components throughout the drawings, and a redundant description thereof will be omitted. In the drawings, thicknesses are enlarged to clearly represent various layers and regions. Also, in the drawings, thicknesses of some layers and regions are exaggerated for convenience of description. Meanwhile, embodiments set forth herein are merely examples and various changes may be made therein.

### [Organometallic Compound]

An organometallic compound according to some example embodiments may be represented by Formula 1:

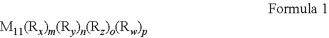

wherein, in Formula 1,
M₁₁ may be indium (In), tin (Sn), antimony (Sb), tellurium (Te), thallium (Tl), lead (Pb), bismuth (Bi), or polonium (Po),
Rₓ may be *—X₁₁—Y₁₁, R_{y} may be *—X₁₂—Y₁₂, and R_{z} may be *—X₁₃—Y₁₃,
R_{w} may be *-(L₁)ₐ₁-(R₁)_{b1},
n may be an integer from 1 to 4, m may be an integer from 1 to 4, o may be an integer from 0 to 4, and p may be an integer from 1 to 4,
m+n+o+p may be 6 or less (e.g., an integer from 0 to 6),
Rₓ and R_{y} may be different from each other,
Formula 1 may optionally include a plurality of Rₓ based on m being greater than 1, the plurality of Rₓ identical to each other,
Formula 1 may optionally include a plurality of R_{y} based on n being greater than 1, the plurality of R_{y} identical to each other,
Formula 1 may optionally include a plurality of R_{z} based on o being greater than 1, the plurality of R_{z} identical to or different from each other,
Formula 1 may optionally include a plurality of R_{w} based on p being greater than 1, the plurality of R_{w} identical to or different from each other,
X₁₁ to X₁₃ may each independently be O, OC(═O), C(═O)O, OS(═O), S(═O)O, OS(═O)₂, S(═O)₂O, S, SC(═O), or C(═O)S,
Y₁₁ to Y₁₃ may each independently be hydrogen, deuterium, or a linear, branched, or cyclic C₁-C₃₀ monovalent hydrocarbon group optionally including a heteroatom (e.g., one or more heteroatoms),
L₁ may be a linear, branched, or cyclic C₁-C₃₀ divalent hydrocarbon group optionally including a heteroatom (e.g., one or more heteroatoms),
a1 may be an integer from 0 to 4,
R₁ may be a linear, branched, or cyclic C₁-C₃₀ monovalent hydrocarbon group optionally including a heteroatom (e.g., one or more heteroatoms),
b1 may be an integer from 1 to 4, wherein Formula 1 may optionally include a plurality of R₁ based on b1 being greater than 1, two adjacent groups among the plurality of R₁ optionally bonded to each other to form a ring, and
* indicates a binding site to a neighboring atom.

The molecular weight of the organometallic compound may be about 3000 g/mol or less. Specifically, the molecular weight of the organometallic compound may be about 2000 g/mol or less. For example, the molecular weight of the organometallic compound may be about 0.1 g/mol or more and about 3000 g/mol or less, or about 0.1 g/mol or more and about 2000 g/mol or less.

For example, in Formula 1, M₁₁ may be Sn, Sb, Te, or Bi. Specifically, in Formula 1, M₁₁ may be Sn.

In Formula 1, m+n+0+p may represent a valence of M₁₁.

For example, in Formula 1, n may be 1 or 2.

For example, in Formula 1, m may be 1 or 2.

For example, in Formula 1, o may be an integer from 0 to 2.

For example, in Formula 1, p may be 1 or 2.

In some example embodiments, in Formula 1, n may be 1 or 2, m may be 1 or 2, o may be an integer from 0 to 2, p may be 1 or 2, m+n+o+p may be 4, and M₁₁ may be Sn.

In Formula 1, a bond between M₁₁ and Rₓ (also referred to herein as a first bond) may be an M₁₁-oxygen single bond or an M₁₁-sulfur single bond. Specifically, in Formula 1, the bond between M₁₁ and Rₓ (e.g., the first bond) may be an M₁₁-oxygen single bond.

In Formula 1, a bond between M₁₁ and R_{y} (also referred to herein as a second bond) may be an M₁₁-oxygen single bond or an M₁₁-sulfur single bond. Specifically, in Formula 1, the bond between M₁₁ and R_{y} (e.g., the second bond) may be an M₁₁-oxygen single bond.

In Formula 1, a bond between M₁₁ and R_{z} (also referred to herein as a third bond) may be an M₁₁-oxygen single bond or an M₁₁-sulfur single bond. Specifically, in Formula 1, the bond between M₁₁ and R_{z} (e.g., the third bond) may be an M₁₁-oxygen single bond.

In Formula 1, a bond between M₁₁ and R_{w} (also referred to herein as a fourth bond) may be an M₁₁-carbon single bond.

In Formula 1, Rₓ and R_{z} may be identical to or different from each other, and R_{y} and R_{z} may be identical to or different from each other.

In some example embodiments, in Formula 1, Rₓ and R_{z} may be different from each other, and R_{y} and R_{z} may be different from each other.

In some example embodiments, in Formula 1, Rₓ and R_{z} may be identical to each other, and R_{y} and R_{z} may be different from each other; or Rₓ and R_{z} may be different from each other, and R_{y} and R_{z} may be identical to each other.

In some example embodiments, the difference in molecular weight between Rₓ and R_{y} may be about 40 g/mol or more. For example, the difference in molecular weight between Rₓ and R_{y} may be in a range of about 40 g/mol to about 1,000 g/mol.

In some example embodiments, o may be 1 or more (e.g., an integer from 1 to 4), and the difference in molecular weight between Rₓ and R_{z} may be 40 g/mol or more (e.g., the difference in molecular weight between Rₓ and R_{y} may be in a range of about 40 g/mol to about 1,000 g/mol).

In some example embodiments, o may be 1 or more (e.g., an integer from 1 to 4), and the difference in molecular weight between R_{y} and R_{z} may be 40 g/mol or more (e.g., the difference in molecular weight between Rₓ and R_{y} may be in a range of about 40 g/mol to about 1,000 g/mol).

In Formula 1, a light sensitivity of Rₓ may be greater than a light sensitivity of R_{y}. In addition, in Formula 1, a moisture sensitivity of Rₓ may be greater than a moisture sensitivity of R_{y}.

For example, in Formula 1, X₁₁ to X₁₃ may each independently be O, OC(═O), C(═O)O, S, SC(═O), or C(═O)S.

Specifically, in Formula 1, X₁₁ to X₁₃ may each independently be OC(═O) or C(═O)O.

For example, in Formula 1, Y₁₁ to Y₁₃ may each independently be hydrogen, deuterium, a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group.

Specifically, in Formula 1, Y₁₁ to Y₁₃ may each independently be selected from: hydrogen; deuterium; and a C₁-C₃₀ alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, and a C₂-C₃₀ heteroarylalkyl group. Each of the C₁-C₃₀ alkyl group, the C₃-C₃₀ cycloalkyl group, the C₃-C₃₀ heterocycloalkyl group, the C₂-C₃₀ alkenyl group, the C₃-C₃₀ cycloalkenyl group, the C₃-C₃₀ heterocycloalkenyl group, the C₂-C₃₀ alkynyl group, the C₆-C₃₀ aryl group, the C₇-C₃₀ arylalkyl group, the C₁-C₃₀ heteroaryl group, and the C₂-C₃₀ heteroarylalkyl group may be unsubstituted or substituted with deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

More specifically, in Formula 1, Y₁₁ to Y₁₃ may each independently be selected from: hydrogen; deuterium; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group. Each of the C₁-C₃₀ alkyl group, the C₃-C₃₀ cycloalkyl group, the C₂-C₃₀ alkenyl group, the C₃-C₃₀ cycloalkenyl group, the C₂-C₃₀ alkynyl group, the C₆-C₃₀ aryl group, and the C₇-C₃₀ arylalkyl group may be unsubstituted or substituted with deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₅-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

In particular, in Formula 1, Y₁₁ to Y₁₃ may each independently be selected from: hydrogen; deuterium; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group. Each of the C₁-C₃₀ alkyl group, the C₃-C₃₀ cycloalkyl group, the C₂-C₃₀ alkenyl group, the C₃-C₃₀ cycloalkenyl group, the C₂-C₃₀ alkynyl group, the C₆-C₃₀ aryl group, and the C₇-C₃₀ arylalkyl group may be unsubstituted or substituted with deuterium, a halogen atom, a cyano group, a nitro group, a carbonyl moiety, a C₁-C₂₀ alkyl group, a C₁-C₂₀ halogenated alkyl group, a C₅-C₂₀ cycloalkyl group, a C₆-C₂₀ aryl group, a C₁-C₂₀ heteroaryl group, or any combination thereof.

In some example embodiments, in Formula 1, Y₁₁ to Y₁₃ may each independently be selected from: hydrogen; deuterium; and Formulae 3-1 to 3-38:

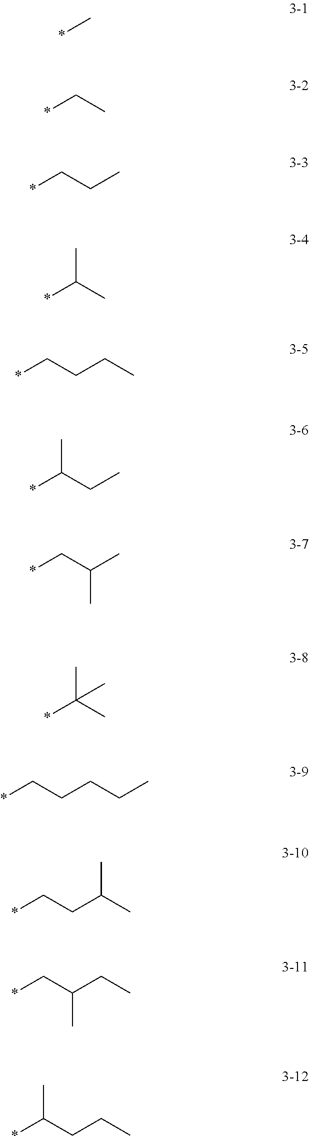

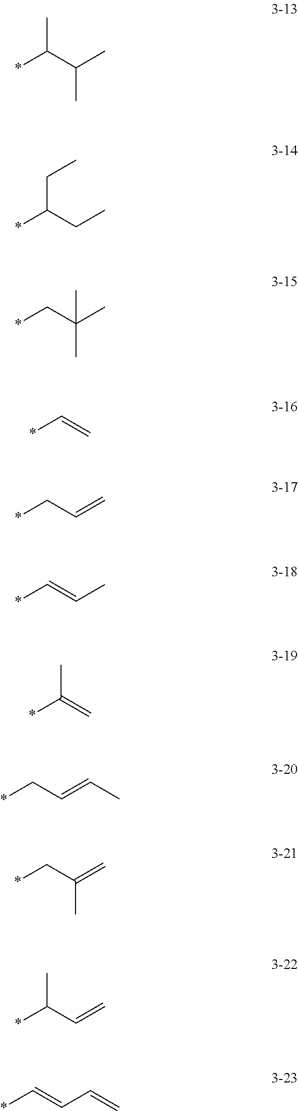

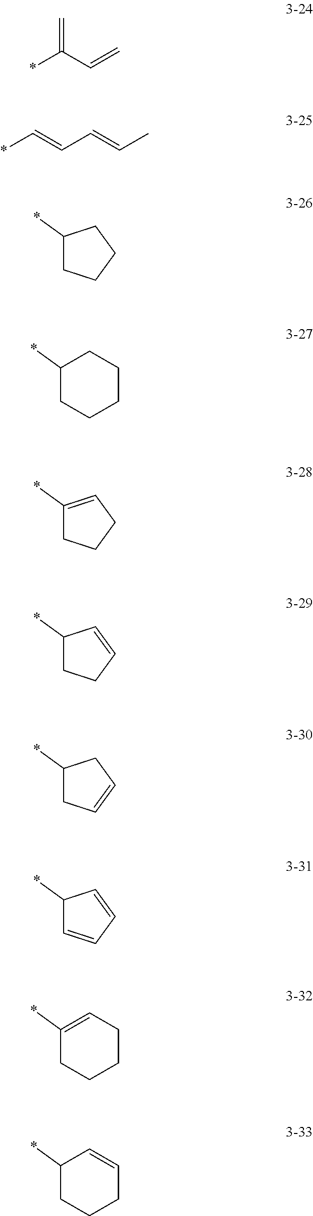

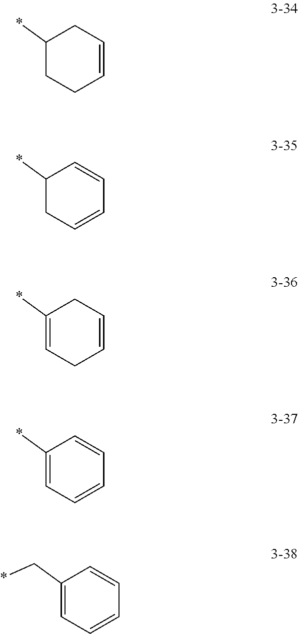

wherein, in Formulae 3-1 to 3-38,
at least one hydrogen may optionally be substituted with deuterium, a halogen atom, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof, and * indicates a binding site to a neighboring atom of Formula 1.

For example, in Formula 1, L₁ may be a single bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

Specifically, in Formula 1, L₁ may be selected from: a single bond; and a C₁-C₃₀ alkylene group, a C₃-C₃₀ cycloalkylene group, a C₃-C₃₀ heterocycloalkylene group, a C₂-C₃₀ alkenylene group, a Cs—C₃₀ cycloalkenylene group, a C₅-C₃₀ heterocycloalkenylene group, a C₆-C₃₀ arylene group, and a C₁-C₃₀ heteroarylene group. Each of the C₁-C₃₀ alkylene group, the C₃-C₃₀ cycloalkylene group, the C₃-C₃₀ heterocycloalkylene group, the C₂-C₃₀ alkenylene group, the C₃-C₃₀ cycloalkenylene group, the C₃-C₃₀ heterocycloalkenylene group, the C₆-C₃₀ arylene group, and the C₁-C₃₀ heteroarylene group may be unsubstituted or substituted with deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, C₁-C₂₀ alkylthio group, C₁-C₂₀ halogenated alkoxy group, C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

More specifically, in Formula 1, L₁ may be selected from: a single bond; and a C₁-C₃₀ alkylene group and a C₆-C₃₀ arylene group. Each of the C₁-C₃₀ alkylene group and the C₆-C₃₀ arylene group may be unsubstituted or substituted with deuterium, a halogen atom, a hydroxyl group, a cyano group, a C₁-C₂₀ alkyl group, a C₁-C₂₀ halogenated alkyl group, or any combination thereof.

In Formula 1, a1 represents the number of repetitions of L₁, and a1 may be an integer of 0, 1, or 2.

In some example embodiments, in Formula 1, (L₁)ₐ₁ may be represented by any one of Formulae 5-1 to 5-7:

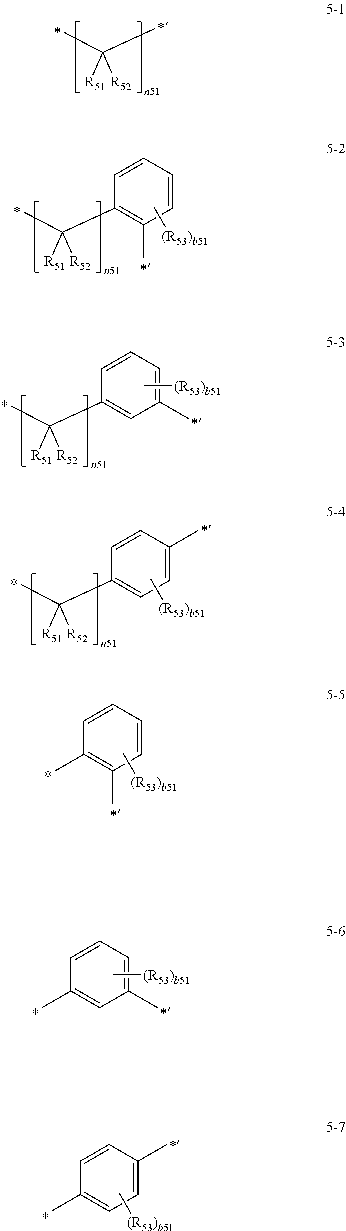

wherein, in Formulae 5-1 to 5-7,
R₅₁ to R₅₃ may each independently be hydrogen, deuterium, a halogen atom, a hydroxyl group, a cyano group, a C₁-C₄ alkyl group, or a C₁-C₄ halogenated alkyl group,
b51 may be an integer from 1 to 4,
n51 may be an integer from 1 to 4, and
* and *′ each indicate a binding site to a neighboring atom of Formula 1.

For example, in Formula 1, R₁ may be a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, a substituted or unsubstituted C₇-C₃₀ arylalkyl group, a substituted or unsubstituted C₁-C₃₀ heteroaryl group, or a substituted or unsubstituted C₂-C₃₀ heteroarylalkyl group.

Specifically, R₁ may be selected from a C₃-C₃₀ cycloalkyl group, a C₅-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, and a C₂-C₃₀ heteroarylalkyl group. Each of the C₃-C₃₀ cycloalkyl group, the C₃-C₃₀ heterocycloalkyl group, the C₂-C₃₀ alkenyl group, the C₃-C₃₀ cycloalkenyl group, the C₃-C₃₀ heterocycloalkenyl group, the C₂-C₃₀ alkynyl group, the C₆-C₃₀ aryl group, the C₇-C₃₀ arylalkyl group, the C₁-C₃₀ heteroaryl group, and the C₂-C₃₀ heteroarylalkyl group may be unsubstituted or substituted with deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₅-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

More specifically, in Formula 1, R₁ may be selected from a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group. Each of the C₃-C₃₀ cycloalkyl group, the C₂-C₃₀ alkenyl group, the C₃-C₃₀ cycloalkenyl group, the C₂-C₃₀ alkynyl group, the C₆-C₃₀ aryl group, and the C₇-C₃₀ arylalkyl group may be unsubstituted or substituted with deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

In particular, in Formula 1, R₁ may be selected from a C₃-C₃₀ cycloalkyl group, a C₂-C₃₀ alkenyl group, a Cs—C₃₀ cycloalkenyl group, a C₂-C₃₀ alkynyl group, a C₆-C₃₀ aryl group, and a C₇-C₃₀ arylalkyl group. Each of the C₃-C₃₀ cycloalkyl group, the C₂-C₃₀ alkenyl group, the Cs—C₃₀ cycloalkenyl group, the C₂-C₃₀ alkynyl group, the C₆-C₃₀ aryl group, and the C₇-C₃₀ arylalkyl group may be unsubstituted or substituted with deuterium, a halogen atom, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof.

In some example embodiments, in Formula 1, R₁ may be selected from Formulae 3-16 to 3-38:

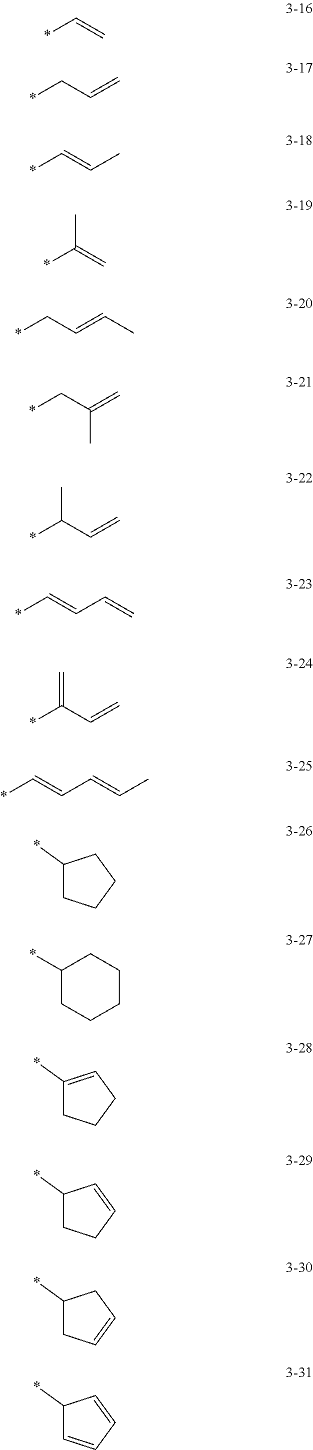

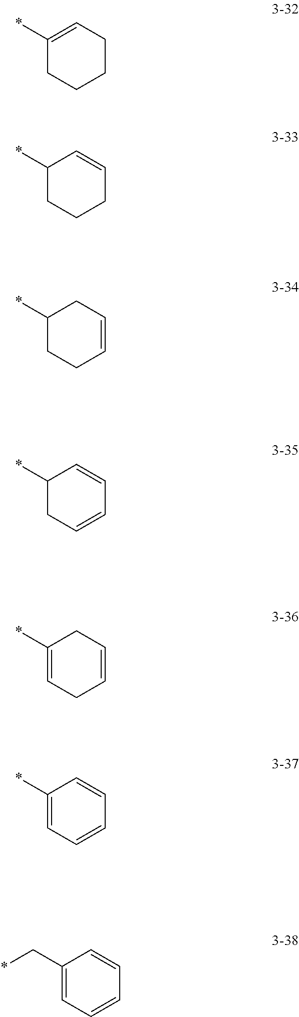

wherein, in Formulae 3-16 to 3-38,
at least one hydrogen may optionally be substituted with deuterium, a halogen atom, a cyano group, a nitro group, a carbonyl moiety, a C₁-C₂₀ alkyl group, a C₁-C₂₀ halogenated alkyl group, a C₅-C₂₀ cycloalkyl group, a C₆-C₂₀ aryl group, a C₁-C₂₀ heteroaryl group, or any combination thereof, and * indicates a binding site to a neighboring atom of Formula 1.

In Formula 1, b1 represents the number (quantity) of substitutions of R₁, and b1 may be 1 or 2.

In some example embodiments, in Formula 1, neighboring two groups among R₁ may optionally be bonded to each other to form a condensed ring.

Specifically, in Formula 1, b1 may be 2 or more, and R₁ may be selected from a C₃-C₃₀ cycloalkyl group, a C₂-C₃₀ alkenyl group, a Cs—C₃₀ cycloalkenyl group, a C₂-C₃₀ alkynyl group, a C₆-C₃₀ aryl group, and a C₇-C₃₀ arylalkyl group, each unsubstituted or substituted with deuterium, a halogen atom, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof.

In some example embodiments, the organometallic compound represented by Formula 1 may be represented by any one of Formulae 1-1 and 1-2:

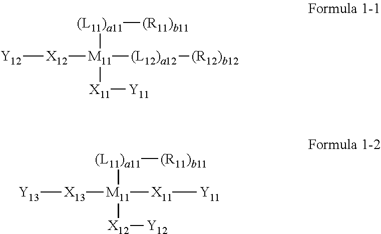

wherein, in Formulae 1-1 and 1-2,
M₁₁, X₁₁ to X₁₃, and Y₁₁ to Y₁₃ may each be the same as described in Formula 1, for example such that M₁₁ may be indium (In), tin (Sn), antimony (Sb), tellurium (Te), thallium (Tl), lead (Pb), bismuth (Bi), or polonium (Po); X₁₁ to X₁₃ may each independently be O, OC(═O), C(═O)O, OS(═O), S(═O)O, OS(═O)₂, S(═O)₂O, S, SC(═O), or C(═O)S; and Y₁₁ to Y₁₃ may each independently be hydrogen, deuterium, or a linear, branched, or cyclic C₁-C₃₀ monovalent hydrocarbon group optionally including a heteroatom (e.g., one or more heteroatoms),
L₁₁ and L₁₂ may each independently be the same as described in connection with L₁ in Formula 1, for example such that L₁₁ and L₁₂ may each independently be a linear, branched, or cyclic C₁-C₃₀ divalent hydrocarbon group optionally including a heteroatom,
a11 and a12 may each independently be the same as described in connection with a1 in Formula 1, for example such that a11 and a12 may each independently be an integer from 0 to 4,
R₁₁ and R₁₂ may each independently be the same as described in connection with R₁ in Formula 1, for example such that R₁₁ and R₁₂ may each independently be a linear, branched, or cyclic C₁-C₃₀ monovalent hydrocarbon group optionally including a heteroatom (e.g., one or more heteroatoms), and
b11 and b12 may each independently be the same as described in connection with b1 in Formula 1, for example such that b11 and b12 may each independently be an integer from 1 to 4, Formulae 1-1 and 1-2 may each optionally include a plurality of R₁₁ based on b11 being greater than 1, two adjacent groups among the plurality of R₁₁ optionally bonded to each other to form a ring; and Formula 1-1 optionally includes a plurality of R₁₂ based on b12 being greater than 1, two adjacent groups among the plurality of R₁₂ optionally bonded to each other to form a ring.

In some example embodiments, the organometallic compound represented by Formula 1 may be selected from Group I:

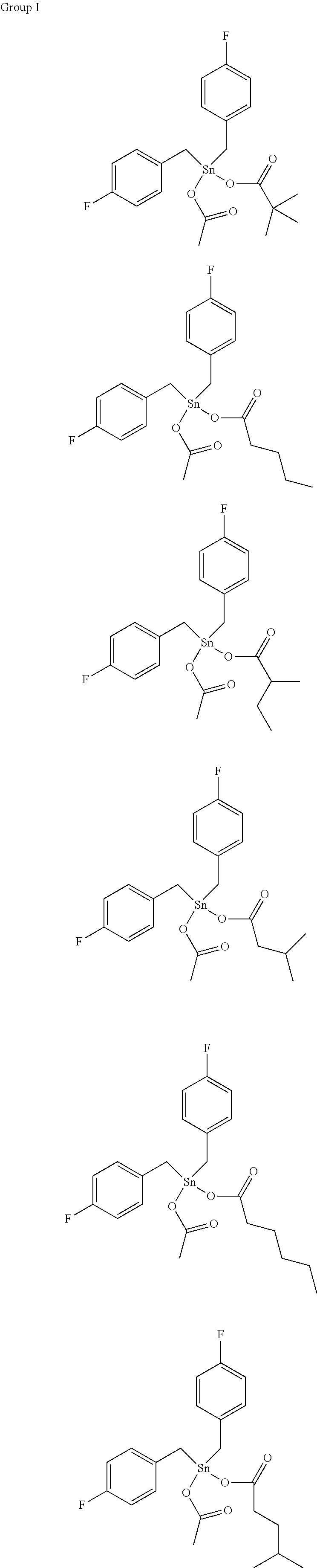

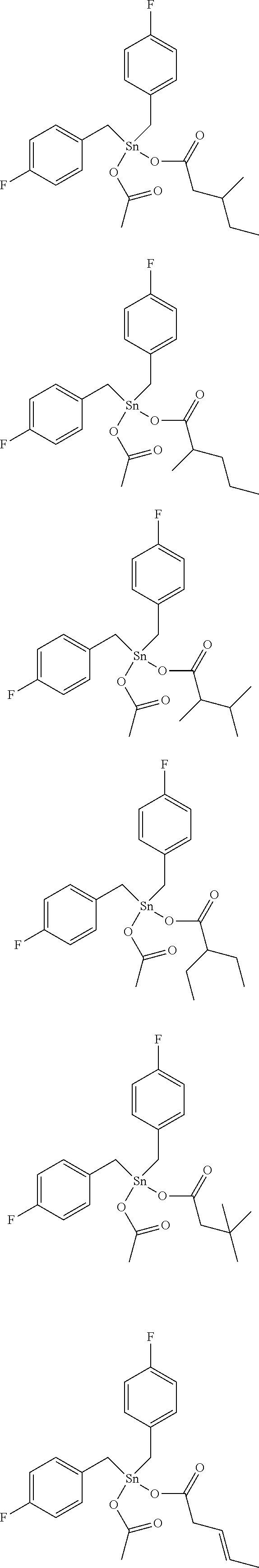 [SMILES: CCC(C)CC(=O)[O][Sn]([CH2]c1ccc(F)cc1)([CH2]c1ccc(F)cc1)[O]C(C)=O ; CCCC(C)C(=O)[O][Sn]([CH2]c1ccc(F)cc1)([CH2]c1ccc(F)cc1)[O]C(C)=O ; CC(=O)[O][Sn]([CH2]c1ccc(F)cc1)([CH2]c1ccc(F)cc1)[O]C(=O)C(C)C(C)C ; CCC(CC)C(=O)[O][Sn]([CH2]c1ccc(F)cc1)([CH2]c1ccc(F)cc1)[O]C(C)=O ; CC(=O)[O][Sn]([CH2]c1ccc(F)cc1)([CH2]c1ccc(F)cc1)[O]C(=O)CC(C)(C)C ; C/C=C/CC(=O)[O][Sn]([CH2]c1ccc(F)cc1)([CH2]c1ccc(F)cc1)[O]C(C)=O]

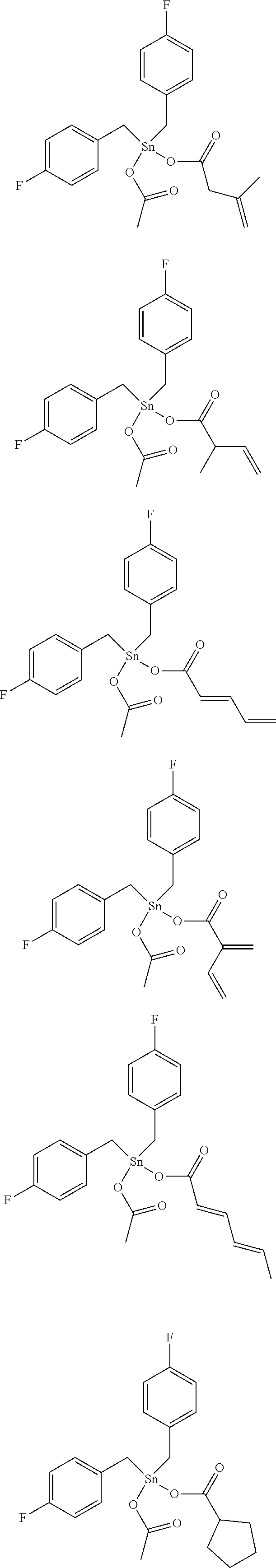

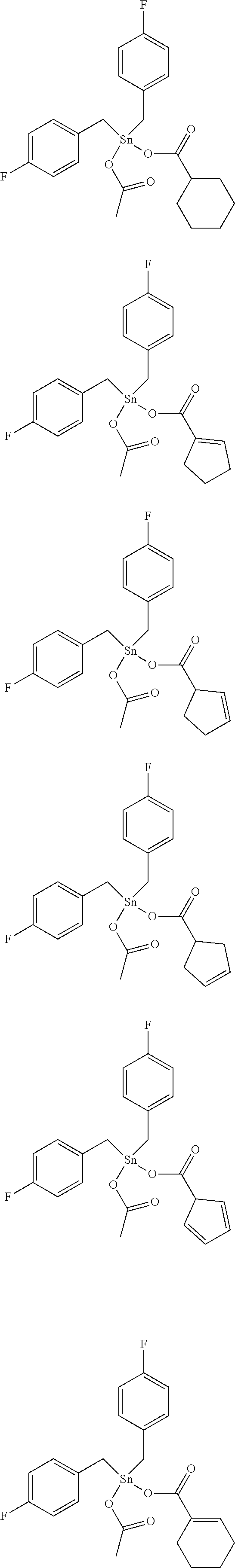 [SMILES: CC(=O)[O][Sn]([CH2]c1ccc(F)cc1)([CH2]c1ccc(F)cc1)[O]C(=O)C1CCCCC1 ; CC(=O)[O][Sn]([CH2]c1ccc(F)cc1)([CH2]c1ccc(F)cc1)[O]C(=O)C1=CCCC1 ; CC(=O)[O][Sn]([CH2]c1ccc(F)cc1)([CH2]c1ccc(F)cc1)[O]C(=O)C1C=CCC1 ; CC(=O)[O][Sn]([CH2]c1ccc(F)cc1)([CH2]c1ccc(F)cc1)[O]C(=O)C1CC=CC1 ; CC(=O)[O][Sn]([CH2]c1ccc(F)cc1)([CH2]c1ccc(F)cc1)[O]C(=O)C1C=CC=C1 ; CC(=O)[O][Sn]([CH2]c1ccc(F)cc1)([CH2]c1ccc(F)cc1)[O]C(=O)C1=CCCCC1]

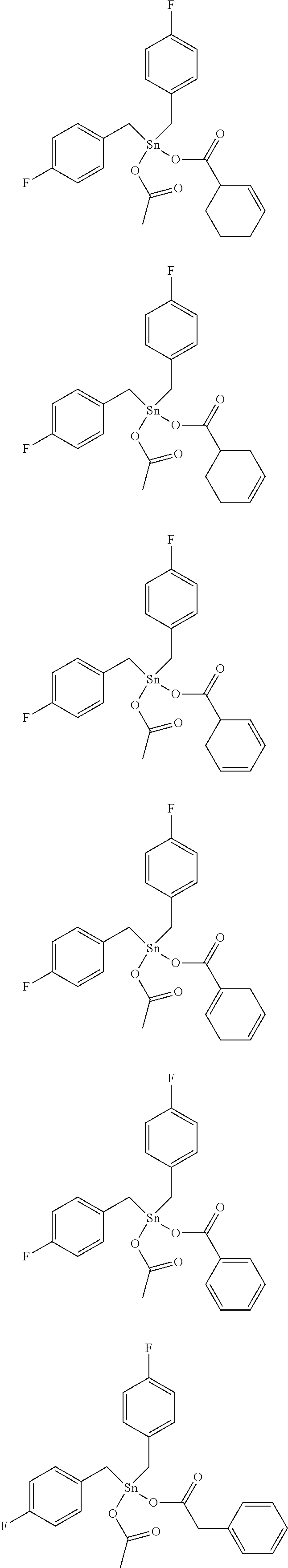 [SMILES: CC(=O)[O][Sn]([CH2]c1ccc(F)cc1)([CH2]c1ccc(F)cc1)[O]C(=O)C1C=CCCC1 ; CC(=O)[O][Sn]([CH2]c1ccc(F)cc1)([CH2]c1ccc(F)cc1)[O]C(=O)C1CC=CCC1 ; CC(=O)[O][Sn]([CH2]c1ccc(F)cc1)([CH2]c1ccc(F)cc1)[O]C(=O)C1C=CC=CC1 ; CC(=O)[O][Sn]([CH2]c1ccc(F)cc1)([CH2]c1ccc(F)cc1)[O]C(=O)C1=CCC=CC1 ; CC(=O)[O][Sn]([CH2]c1ccc(F)cc1)([CH2]c1ccc(F)cc1)[O]C(=O)c1ccccc1 ; CC(=O)[O][Sn]([CH2]c1ccc(F)cc1)([CH2]c1ccc(F)cc1)[O]C(=O)Cc1ccccc1]

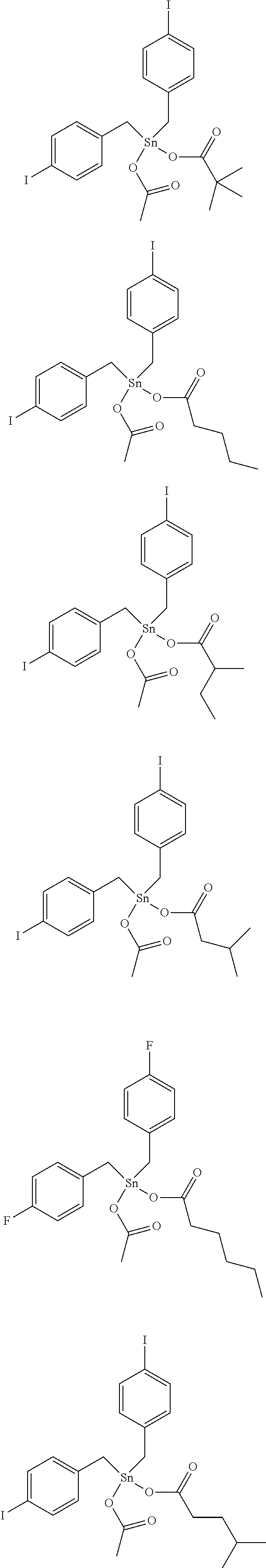

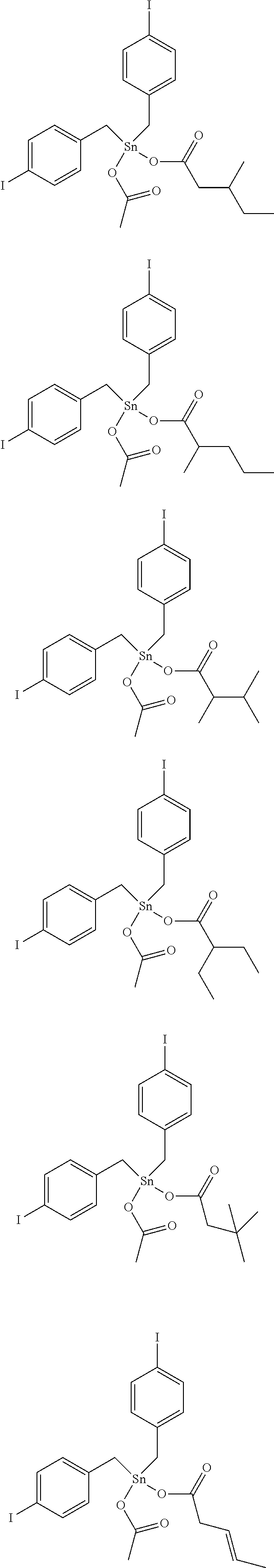

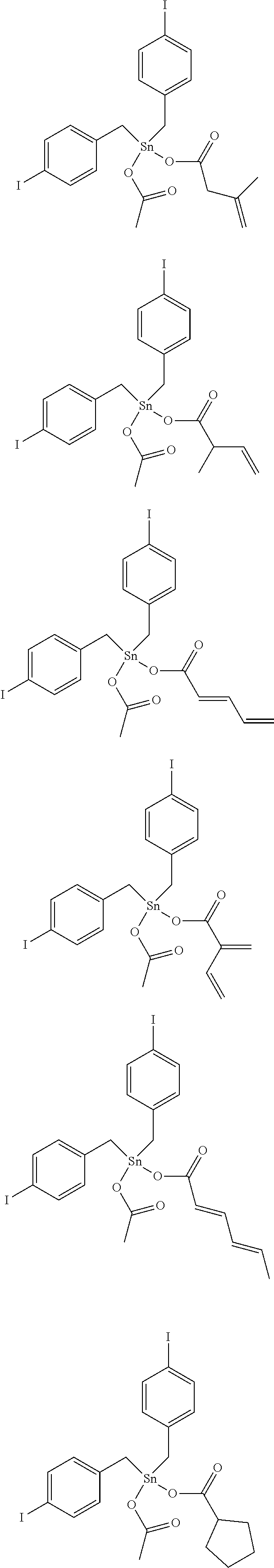

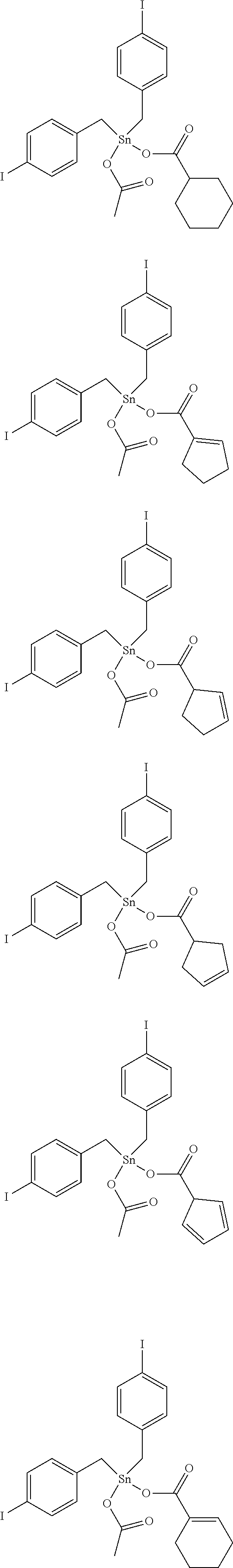 [SMILES: CC(=O)[O][Sn]([CH2]c1ccc(I)cc1)([CH2]c1ccc(I)cc1)[O]C(=O)C1CCCCC1 ; CC(=O)[O][Sn]([CH2]c1ccc(I)cc1)([CH2]c1ccc(I)cc1)[O]C(=O)C1=CCCC1 ; CC(=O)[O][Sn]([CH2]c1ccc(I)cc1)([CH2]c1ccc(I)cc1)[O]C(=O)C1C=CCC1 ; CC(=O)[O][Sn]([CH2]c1ccc(I)cc1)([CH2]c1ccc(I)cc1)[O]C(=O)C1CC=CC1 ; CC(=O)[O][Sn]([CH2]c1ccc(I)cc1)([CH2]c1ccc(I)cc1)[O]C(=O)C1C=CC=C1 ; CC(=O)[O][Sn]([CH2]c1ccc(I)cc1)([CH2]c1ccc(I)cc1)[O]C(=O)C1=CCCCC1]

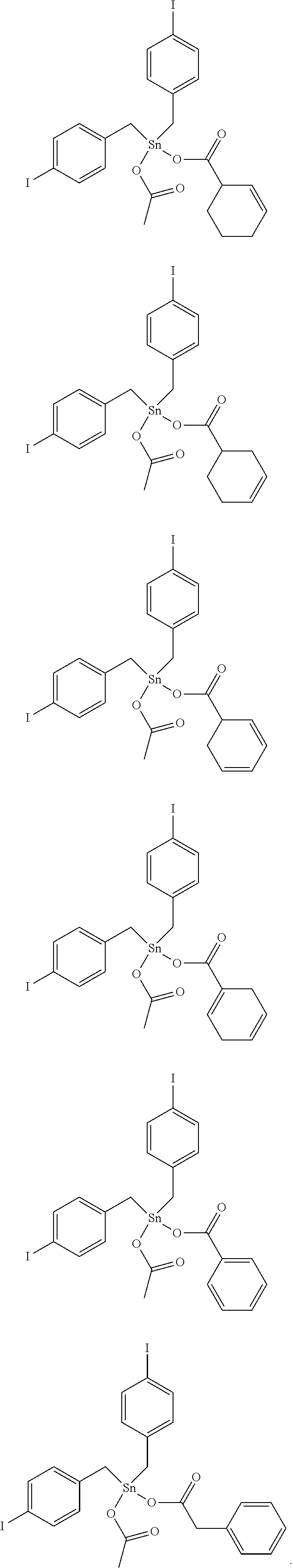 [SMILES: CC(=O)[O][Sn]([CH2]c1ccc(I)cc1)([CH2]c1ccc(I)cc1)[O]C(=O)C1C=CCCC1 ; CC(=O)[O][Sn]([CH2]c1ccc(I)cc1)([CH2]c1ccc(I)cc1)[O]C(=O)C1CC=CCC1 ; CC(=O)[O][Sn]([CH2]c1ccc(I)cc1)([CH2]c1ccc(I)cc1)[O]C(=O)C1C=CC=CC1 ; CC(=O)[O][Sn]([CH2]c1ccc(I)cc1)([CH2]c1ccc(I)cc1)[O]C(=O)C1=CCC=CC1 ; CC(=O)[O][Sn]([CH2]c1ccc(I)cc1)([CH2]c1ccc(I)cc1)[O]C(=O)c1ccccc1 ; CC(=O)[O][Sn]([CH2]c1ccc(I)cc1)([CH2]c1ccc(I)cc1)[O]C(=O)Cc1ccccc1]

Although not limited to a specific theory, in the organometallic compound, radicals may be generated by high-energy rays, and chemical bonds may be formed between the radicals.

Recently, to overcome the limitations of chemically amplified resists, inorganic resists based on organometallic compounds (or metal-organic resists (MORs)) have been actively developed.

Existing inorganic resists may be hydrolyzed by moisture during the storage process at the bonds between the metal-heteroelement (e.g., oxygen)-containing ligands, which may cause precipitation and ultimately lead to difficulties in applying the resists to a pattern formation process.

However, by adjusting the organometallic compound represented by Formula 1 to include different types of heteroelement-containing ligands, the solution stability and/or thin film stability may be improved while maintaining the solubility and photosensitivity.

In view of at least the above, the organometallic compound may have a composition which has improved storage stability and/or which may enable a resist composition including the organometallic compound to have improved storage stability. In view of at least the above, the organometallic compound may enable a resist composition including same to be configured to change one or more physical properties even by exposure to incident light (e.g., high-energy rays), based on the resist composition including the organometallic compound represented by Formula 1, in order to overcome limitations of chemically amplified resists which may cause a formed acid to diffuse to an unexposed region.

As a result, a resist composition may be configured to reduce, minimize, or prevent the likelihood of a reduction in uniformity of patterns and/or an increase in surface roughness when the resist composition is used in a pattern formation method, based on avoiding such formed acid diffusion, while simultaneously providing improved resist composition chemical stability (and thereby reduced, minimized, or prevented risk of chemical deterioration) in normal usage environments at room temperature and/or while simultaneously changing physical properties even by exposure to a small amount (e.g., small intensity) of incident light (e.g., high-energy rays), based on the resist composition including the organometallic compound represented by Formula 1.

The organometallic compound may be manufactured by any suitable method.

The structure (composition) of the organometallic compound may be confirmed by performing Fourier transform infrared spectroscopy (FT-IR) analysis, nuclear magnetic resonance (NMR) analysis, X-ray fluorescence (XRF) analysis, mass spectrometry, ultraviolet (UV) analysis, single crystal X-ray structural analysis, powder X-ray diffraction (PXRD) analysis, liquid chromatography (LC) analysis, size exclusion chromatography (SEC) analysis, thermal analysis, and the like. The detailed verification method is as described in the following Examples.

### [Resist Composition]

According to some example embodiments of the inventive concepts, provided is a resist composition including the above-described organometallic compound (e.g., an organometallic compound represented by Formula 1). The organometallic compound may be referred to as a “first organometallic compound” of the resist composition, such that the resist composition may be referred to as including a first organometallic compound, the first organometallic compound being the organometallic compound represented by Formula 1. The resist composition may have improved photosensitivity and/or storage stability characteristics based on including such an organometallic compound.

In view of at least the above, the resist composition may have a composition which has improved storage stability and/or the resist composition may be configured to change one or more physical properties even by exposure to incident light (e.g., high-energy rays), in order to overcome limitations of chemically amplified resists which may cause a formed acid to diffuse to an unexposed region, based on the resist composition including the organometallic compound represented by Formula 1 according to any of the example embodiments. As a result, the resist composition may be configured to reduce, minimize, or prevent the likelihood of a reduction in uniformity of patterns and/or an increase in surface roughness when the resist composition is used in a pattern formation method, based on avoiding such formed acid diffusion, while simultaneously providing improved resist composition chemical stability (and thereby reduced, minimized, or prevented risk of chemical deterioration) in normal usage environments at room temperature and/or while simultaneously changing physical properties even by exposure to a small amount (e.g., small intensity) of incident light (e.g., high-energy rays).

The solubility of the resist composition in a developer may change by exposure to high-energy rays. The resist composition may be a positive-type resist composition in which an exposed portion of a resist film is dissolved and removed to form a resist pattern.

In addition, the resist composition may be for a distilled water (DI) development process using DI for the development process when forming a resist pattern, for an alkaline development process using an alkaline developer, or for a solvent development process using a developer including an organic solvent (hereinafter, also referred to as an organic developer) for the development process.

In particular, the resist composition may provide a pattern with improved critical dimension (CD) uniformity by using DI or an organic solvent as a developer, or by using an alkaline developer including a relatively small amount of alkaline components.

Since the resist composition is a non-chemically amplified type, it may substantially not include a photoacid generator (e.g., may not include any photoacid generators). For example, the resist composition may be free or substantially free of any photoacid generators (e.g., may not include any or substantially any photoacid generators).

The resist composition may not substantially include compounds having a molecular weight of about 1,000 or more other than the organometallic compound, since the physical properties of the organometallic compound may change by exposure. For example, the resist composition may be free or substantially free of any compounds having a molecular weight of about 1,000 or more (e.g., may not include any or substantially any compounds having a molecular weight of about 1,000 or more).

In the resist composition, an amount of the organometallic compound may be in a range of about 0.1 parts by weight to about 100 parts by weight, specifically, about 0.2 parts by weight or more, about 0.5 parts by weight or more, about 1 part by weight or more, about 2 parts by weight or more, about 90 parts by weight or less, or about 80 parts by weight or less, or any combination thereof, based on 100 parts by weight of the resist composition. When the amount of the organometallic compound is within these ranges, a resist composition having improved sensitivity and/or resolution may be provided while forming a film having a thickness required for pattern formation and suppressing side reactions.

The resist composition may further include at least one selected from a second organometallic compound represented by Formula 2-1 and a third organometallic compound represented by Formula 2-2 (e.g., the resist composition may further include at least one of a second organometallic compound represented by Formula 2-1 or a third organometallic compound represented by Formula 2-2),
the organometallic compound (e.g., the first organometallic compound) and the second organometallic compound may be different from each other,
the organometallic compound (e.g., the first organometallic compound) and the third organometallic compound may be different from each other, and
the second organometallic compound and the third organometallic compound may be different from each other:

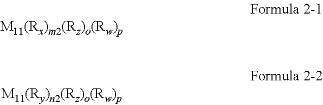

wherein, in Formulae 2-1 and 2-2,
M₁₁ may be indium (In), tin (Sn), antimony (Sb), tellurium (Te), thallium (Tl), lead (Pb), bismuth (Bi), or polonium (Po),
Rₓ may be *—X₁₁—Y₁₁, R_{y} may be *—X₁₂—Y₁₂, and R_{z} may be *—X₁₃—Y₁₃,
R_{w} may be *-(L₁)ₐ₁-(R₁)_{b1},
n2 may be an integer from 2 to 4, m2 may be an integer from 2 to 4, o may be an integer from 0 to 4, and p may be an integer from 1 to 4,
m2+o+p may be 6 or less (e.g., an integer from 0 to 6), and n2+o+p may be 6 or less (e.g., an integer from 0 to 6),
Formula 2-1 may optionally include a plurality of Rₓ based on m2 being greater than 1, the plurality of Rₓ identical to each other,
Formula 2-2 may optionally include a plurality of R_{y} based on n2 being greater than 1, the plurality of R_{y} identical to each other,
Formulae 2-1 and 2-2 may each optionally include a plurality of R_{z} based on o being greater than 1, the plurality of R_{z} identical to or different from each other,
Formulae 2-1 and 2-2 may each optionally include a plurality of R_{w} based on p being greater than 1, the plurality of R_{w} identical to or different from each other,
X₁₁ to X₁₃ may each independently be O, OC(═O), C(═O)O, OS(═O), S(═O)O, OS(═O)₂, S(═O)₂O, S, SC(═O), or C(═O)S,
Y₁₁ to Y₁₃ may each independently be hydrogen, deuterium, or a linear, branched, or cyclic C₁-C₃₀ monovalent hydrocarbon group optionally including a heteroatom (e.g., one or more heteroatoms),
L₁ may be a linear, branched, or cyclic C₁-C₃₀ divalent hydrocarbon group optionally including a heteroatom (e.g., one or more heteroatoms),
a1 may be an integer from 0 to 4,
R₁ may be a linear, branched, or cyclic C₁-C₃₀ monovalent hydrocarbon group optionally including a heteroatom (e.g., one or more heteroatoms),
b1 may be an integer from 1 to 4, wherein Formulae 2-1 and 2-2 may each optionally include a plurality of R₁ based on b1 being greater than 1, two adjacent groups among the plurality of R₁ optionally bonded to each other to form a ring, and
* indicates a binding site to a neighboring atom of Formula 2-1 or Formula 2-2.

### <Organic Solvent>

The resist composition may further include an organic solvent.

The organic solvent included in the resist composition is not particularly limited as long as the organic solvent is capable of dissolving or dispersing the organometallic compound and optional components included as needed. The organic solvent may be used singly or in a combination of two or more.

In some example embodiments, the organic solvent may include a nonpolar solvent, a polar protic organic solvent, a polar aprotic organic solvent, or any combination thereof.

In some example embodiments, the organic solvent may be a polar aprotic organic solvent.

Examples of the polar protic solvent may include an alcohol-based solvent and the like.

Examples of the polar aprotic solvent may include an ether-based solvent, a ketone-based solvent, an amide-based solvent, an ester-based solvent, a sulfoxide-based solvent, and the like.

Examples of the nonpolar solvent may include a hydrocarbon-based solvent and the like.

More specifically, the alcohol-based solvent may include: a monoalcohol-based solvent, such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, and diacetone alcohol; a polyhydric alcohol-based solvent, such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, and tripropylene glycol; and a polyhydric alcohol-containing ether-based solvent, such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, and dipropylene glycol monopropyl ether.

Examples of the ether-based solvent may include: a dialkyl ether-based solvent, such as diethyl ether, dipropyl ether, dibutyl ether, diethylene glycol dimethyl ether, and dipropylene glycol dimethyl ether; a cyclic ether-based solvent, such as tetrahydrofuran and tetrahydropyran; and an aromatic ring-containing ether-based solvent, such as diphenyl ether and anisole.

Examples of the ketone-based solvent may include: a chain ketone-based solvent, such as acetone, methyl ethyl ketone, methyl-n-propyl ketone, methyl-n-butyl ketone, methyl-n-pentyl ketone, diethyl ketone, methyl isobutyl ketone, 2-heptanone, ethyl-n-butyl ketone, methyl-n-hexyl ketone, diisobutyl ketone, and trimethylnonanone; a cyclic ketone-based solvent, such as cyclopentanone, cyclohexanone, cycloheptanone, cyclooctanone, and methylcyclohexanone; and 2,4-pentanedione, acetonyl acetone, and acetophenone.

Examples of the amide-based solvent may include: a cyclic amide-based solvent, such as N,N′-dimethylimidazolidinone and N-methyl-2-pyrrolidone; and a chain amide-based solvent, such as N-methylformamide, N,N-dimethylformamide, N,N-diethylformamide, acetamide, N-methylacetamide, N,N-dimethylacetamide, and N-methylpropionamide.

Examples of the ester-based solvent may include: an acetate ester-based solvent, such as methyl acetate, ethyl acetate, n-propyl acetate, isopropyl acetate, n-butyl acetate, isobutyl acetate, sec-butyl acetate, t-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, and n-nonyl acetate; a polyhydric alcohol-containing ether carboxylate-based solvent, such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate (PGMEA), propylene glycol monoethyl ether acetate, propylene glycol monopropyl ether acetate, propylene glycol monobutyl ether acetate, dipropylene glycol monomethyl ether acetate, and dipropylene glycol monoethyl ether acetate; a lactone-based solvent, such as γ-butyrolactone and δ-valerolactone; a carbonate-based solvent, such as dimethyl carbonate, diethyl carbonate, ethylene carbonate, and propylene carbonate; a lactate ester-based solvent, such as methyl lactate, ethyl lactate, n-butyl lactate, and n-amyl lactate; and glycoldiacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, and diethyl phthalate.

Examples of the sulfoxide-based solvent may include dimethyl sulfoxide and diethyl sulfoxide.

Examples of the hydrocarbon-based solvent may include: an aliphatic hydrocarbon-based solvent, such as n-pentane, isopentane, n-hexane, isohexane, n-heptane, isoheptane, 2,2,4-trimethylpentane, n-octane, isooctane, cyclohexane, and methylcyclohexane; and an aromatic hydrocarbon-based solvent, such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, and n-amylnaphthalene.

Specifically, the organic solvent may include a chain ketone-based solvent, a cyclic ketone-based solvent, a polyhydric alcohol-containing ether carboxylate-based solvent, a lactate ester-based solvent, an acetate ester-based solvent, and any combination thereof.

More specifically, the organic solvent may include cyclopentanone, cyclohexanone, cycloheptanone, propylene glycol monomethyl ether acetate, propylene glycol monoethyl ether acetate, propylene glycol monopropyl ether acetate, propylene glycol monobutyl ether acetate, methyl lactate, ethyl lactate, n-butyl lactate, n-amyl lactate, and any combination thereof.

Since the resist composition may be free or substantially free of water, the organic solvent may be free or substantially free of water. Specifically, the resist composition may include about 3 wt % or less of water (e.g., 0.01 wt % to 3 wt %, 0.1 wt % to 3 wt %, 1 wt % to 3 wt %, etc.), and the organic solvent may include about 3 wt % or less of water (e.g., 0.01 wt % to 3 wt %, 0.1 wt % to 3 wt %, 1 wt % to 3 wt %, etc.).

The organic solvent may be used in an amount of about 0 parts by weight to about 99.9 parts by weight based on 100 parts by weight of the resist composition (e.g., about 0.01 parts by weight to about 99.9 parts by weight, about 0.1 parts by weight to about 99.9 parts by weight, about 1 part by weight to about 99.9 parts by weight, etc.). The organic solvent may be used alone, or in combination with two or more different types.

### <Optional Components>

The resist composition may further include a surfactant, a crosslinking agent, a leveling agent, a colorant, or any combination thereof as needed.

The resist composition may further include a surfactant to improve coatability, developability, and the like. Specific examples of the surfactant may include a nonionic surfactant, such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate. As the surfactant, a commercially available product or a synthetic product may be used. Examples of the commercially available product of the surfactant may include KP341 (manufactured by Shin-Etsu Chemical Co., Ltd.), Polyflow No. 75 and Polyflow No. 95 (manufactured by Kyoeisha Chemical Co., LTD.), Eftop EF301, Eftop 303, and Eftop 352 (manufactured by Mitsubishi Materials Electronic Chemicals Co., Ltd.), MEGAFACE® F171, MEGAFACE® F173, R-40, R-41, and R-43 (manufactured by DIC Corporation), FLUORAD® FC430 and FLUORAD® FC431 (manufactured by 3M, Co.,), ASAHI GUARD® AG710 (manufactured by AGC Co., Ltd.), and SURFLON® S-382, SURFLON® SC-101, SURFLON® SC-102, SURFLON® SC-103, SURFLON® SC-104, SURFLON® SC-105, and SURFLON® SC-106 (manufactured by AGC Seimi Chemical Co., Ltd.).

The surfactant may be included in an amount of about 0 parts by weight to about 20 parts by weight based on 100 parts by weight of the organometallic compound. The surfactant may be used singly or in a combination of two or more.

A method of manufacturing the resist composition is not particularly limited, and for example, a method of mixing an organometallic compound and optional components added as needed in an organic solvent, may be used. A temperature or time during mixing is not particularly limited. If necessary, filtration may be performed after mixing.

### [Pattern Formation Method]

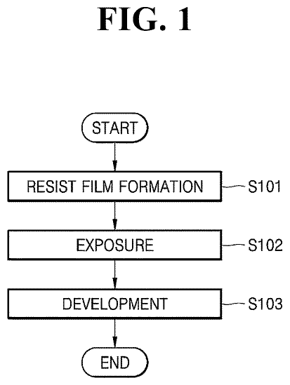

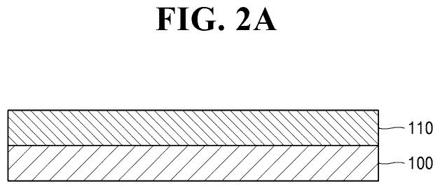

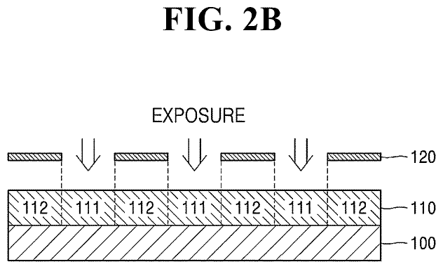

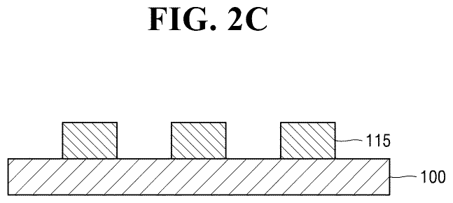

Hereinafter, a pattern formation method according to some example embodiments will be described in more detail with reference to FIGS. 1 and 2A to 2C. FIG. 1 is a flowchart illustrating a pattern formation method according to some example embodiments, and FIGS. 2A to 2C are side cross-sectional views illustrating a pattern formation method according to some example embodiments. Hereinafter, a pattern formation method using a negative-type resist composition as the resist composition will be described as an example, but the inventive concepts are not limited thereto.

Referring to FIG. 1, the pattern formation method may include applying a resist composition onto a substrate to form a resist film (S101), exposing at least a portion of the resist film to high-energy rays to form an exposed resist film (S102), and developing the exposed resist film based on using a developer (S103). Such operations may be omitted if necessary, or may be performed in a different order.

First, referring to FIG. 1 and FIG. 2A, a substrate 100 may be prepared. The substrate 100 may include, for example, a semiconductor substrate such as a silicon substrate or a germanium substrate, glass, quartz, ceramic, copper, and the like. In some example embodiments, the substrate 100 may include a Group III-Group V compound such as GaP, GaAs, and GaSb.

A resist composition may be applied to a desired thickness onto the substrate 100 by, specifically, coating, to form a resist film 110. The applied resist composition may be the resist composition as described herein according to any of the example embodiments. Accordingly, the resist film 110 may include the resist composition according to any of the example embodiments. If necessary, a post application bake (PAB) may be performed to remove an organic solvent remaining on the resist film 110.

As the coating method, spin coating, dipping, roller coating, or other general coating methods may be used. Among the coating methods, in particular, spin coating may be used, and the viscosity, concentration, and/or spin speed of the resist composition may be adjusted to form a resist film 110 having a desired thickness. Specifically, the thickness of the resist film 110 may be about 10 nm to about 300 nm. More specifically, the thickness of the resist film 110 may be about 30 nm to about 200 nm.

The lower limit of the temperature of the PAB may be about 60° C. or higher, specifically about 80° C. or higher. In some example embodiments, the upper limit of the temperature of the PAB may be about 150° C. or less, specifically about 140° C. or less. The lower limit of the PAB time may be about 5 seconds or more, specifically about 10 seconds or more. The upper limit of the PAB time may be about 600 seconds or less, specifically about 300 seconds or less.

Before applying a resist composition onto a substrate 100, an etching target film (not shown) may be further formed on the substrate 100. The etching target film may refer to a layer in which an image is transferred from a resist pattern 115 and converted into a particular (or, alternatively, predetermined) pattern. In some example embodiments, the etching target film may be formed to include, for example, an insulating material such as silicon oxide, silicon nitride, or silicon oxynitride. In some example embodiments, the etching target film may be formed to include a conductive material such as a metal, metal nitride, metal silicide, or metal silicide nitride. In some example embodiments, the etching target film may be formed to include a semiconductor material such as polysilicon.

In some example embodiments, an antireflection film may be further formed on the substrate 100 to increase or maximize the efficiency of a resist. The antireflection film may be an organic or inorganic antireflection film.

In some example embodiments, a protective film may be further provided on the resist film 110 to reduce the influence of alkaline impurities or the like included during a process. In addition, when immersion exposure is performed, for example, a protective film for immersion may be provided on the resist film 110 to avoid direct contact between an immersion medium and the resist film 110.

Next, referring to FIG. 1 and FIG. 2B, at least a portion of the resist film 110 may be exposed to high-energy rays, thereby establishing an exposed resist film. For example, high-energy rays passing through a mask 120 may be irradiated onto at least a portion of the resist film 110. Accordingly, based on the exposing, the resist film 110 (e.g., the exposed resist film) may have an exposed portion 111 and an unexposed portion 112.

Although not limited to a specific theory, radicals may be generated in the exposed portion 111 by exposure, and chemical bonds may be formed between the radicals, which may change the physical properties of the resist composition.

In some example embodiments, the exposure may be performed by irradiating high-energy rays through a mask 120 with a particular (or, alternatively, predetermined) pattern using a liquid such as water as a medium. Examples of the high-energy rays may include: electromagnetic waves such as ultraviolet rays, deep ultraviolet (DUV) rays, extreme ultraviolet (EUV) rays (with a wavelength of 13.5 nm), X-rays, and a γ-rays; charged particle beams such as electron beams (EBs) and α-rays; and the like. Irradiating the high-energy rays may be collectively referred to as “exposure.”

As the method using the exposure light source, various methods may be used including emitting laser light in the ultraviolet light region, such as KrF excimer lasers (wavelength 248 nm), ArF excimer lasers (wavelength 193 nm), and F₂ excimer lasers (wavelength 157 nm), emitting harmonic laser light in the DUV region or vacuum ultraviolet region by converting the wavelength of laser light from solid-state laser sources (such as YAG or semiconductor lasers), and irradiating EBs or EUV rays. During exposure, the exposure may be usually performed through a mask corresponding to a desired pattern, but when exposure light source is an EB, the exposure may be performed through direct writing without using a mask.

When an EUV is used as the high-energy ray, the integrated dose of the high-energy ray may be about 2000 mJ/cm² or less, specifically about 500 mJ/cm² or less and may be greater than 0 mJ/cm², for example 0.01 mJ/cm² or more, for example 0.1 mJ/cm² or more, for example 1 mJ/cm² or more. In addition, when an EB is used as the high-energy ray, the integrated dose may be about 5000 μC/cm² or less, specifically about 1000 μC/cm² or less and may be greater than 0 mJ/cm², for example 0.01 mJ/cm² or more, for example 0.1 mJ/cm² or more, for example 1 mJ/cm² or more.

In addition, post exposure bake (PEB) may be performed. The lower limit of the temperature of PEB may be about 50° C. or higher, specifically about 80° C. or higher. The upper limit of the temperature of PEB may be about 180° C. or less, specifically about 130° C. or less. The lower limit of the PEB time may be about 5 seconds or more, specifically about 10 seconds or more. The upper limit of the PEB time may be about 600 seconds or less, specifically about 300 seconds or less.

Next, referring to FIG. 1 and FIG. 20, the exposed resist film 110 may be developed by using a developer to form a resist pattern 115. At this time, the unexposed portion 112 may be washed away and removed by the developer, and the exposed portion 111 may remain without being washed away by the developer. The resultant structure as shown in FIG. 2C may be and/or may define a resist pattern 115.

Examples of the developer may include an alkaline developer, a developer including an organic solvent (hereinafter also referred to as “organic developer”), and the like. Examples of a developing method may include a dipping method, a puddle method, a spray method, a dynamic injection method, and the like. A developing temperature may be, for example, about 5° C. to about 60° C., and a developing time may be, for example, about 5 seconds to about 300 seconds.

The alkaline developer may include, for example, an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, tetramethylammonium hydroxide (TMAH), pyrrole, piperidine, choline, 1,8-diazabicyclo[5.4.0]-7-undecene (DBU), and 1,5-diazabicyclo[4.3.0]-5-nonene (DBN) are dissolved. The alkaline developer may further include a surfactant.

The lower limit of the amount of the alkaline compound in the alkaline developer may be about 0.1 wt % or more, specifically about 0.5 wt % or more, and more specifically about 1 wt % or more. Additionally, the upper limit of the amount of the alkaline compound in the alkaline developer may be about 20 wt % or less, specifically about 10 wt % or less, and more specifically about 5 wt % or less.

After development, the resist pattern 115 may be cleaned with ultrapure water, and then water remaining on the substrate and pattern may be removed therefrom.

Examples of the organic solvent included in the organic developer may include the same organic solvents as those exemplified in the part of <Organic solvent> of [Resist composition].

Specifically, n-butyl acetate (nBA), propylene glycol monomethyl ether (PGME), propylene glycol monomethyl ether acetate (PGMEA), ethyl lactate, γ-butyrolactone (GBL), isopropanol (IPA), and the like may be used as the organic developer. The organic developer may further include an organic acid such as acetic acid, formic acid, citric acid, and the like.

The lower limit of the amount of the organic solvent in the organic developer may be about 80 wt % or more, specifically about 90 wt % or more, more specifically about 95 wt % or more, and especially about 99 wt % or more.

In some example embodiments, the developer may include distilled water, an alkaline developer, or any combination thereof, and the unexposed portion 112 may be removed by the developer.

The organic developer may also include a surfactant. In addition, a trace amount of water may be included in the organic developer. Additionally, during development, development may be stopped by substitution with a different kind of solvent from the organic developer.

The resist pattern 115 after development may be further cleaned. Ultrapure water, a rinse solution, and the like may be used as a cleaning solution. A rinse solution is not particularly limited as long as the rinse solution does not dissolve a resist pattern 115, and a solution including a general organic solvent may be used. For example, the rinse solution may be an alcohol-based solvent or an ester-based solvent. After the cleaning, the rinse solution remaining on the substrate and pattern may be removed. In addition, when the ultrapure water is used, water remaining on the substrate and pattern may be removed.

In addition, developers may be used singly or in a combination of two or more.

After the resist pattern 115 is formed as described above, a pattern interconnection substrate may be obtained through etching. The etching may be performed through a known method including dry etching using a plasma gas and wet etching using an alkaline solution, a copper (II) chloride solution, an iron (II) chloride solution, and the like.

After the resist pattern 115 is formed, plating may be performed. The plating is not particularly limited, and examples thereof may include copper plating, solder plating, nickel plating, gold plating, and the like.

The resist pattern 115 remaining after the etching may be peeled off with an organic solvent. Examples of such organic solvent may include, but are not limited to, PGMEA, PGME, ethyl lactate (EL), and the like. A peeling method is not particularly limited, but examples thereof may include an immersion method, a spray method, and the like. In addition, the interconnection substrate on which the resist pattern 115 is formed may be a multilayer interconnection substrate or may have small-diameter through-holes.

In some example embodiments, the interconnection substrate may be formed through a method of forming a resist pattern 115, depositing a metal in a vacuum, and then melting the resist pattern 115 with a solution, that is, a lift-off method.

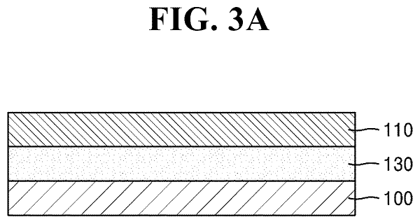

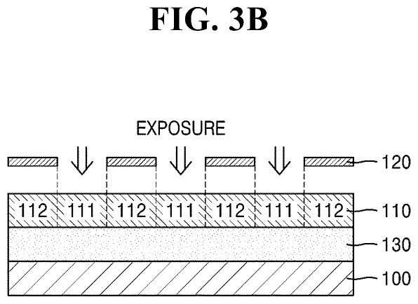

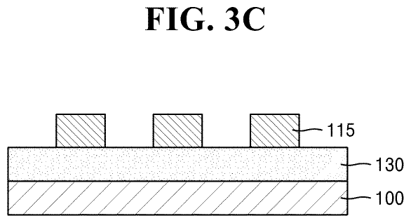

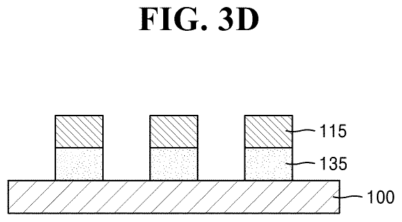

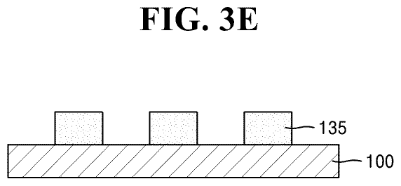

FIGS. 3A, 3B, 3C, 3D, and 3E are side cross-sectional views illustrating a method of forming a patterned structure according to some example embodiments.

As shown in FIG. 3A, a material layer 130 may be formed on a substrate 100 before forming a resist film 110 on the substrate 100. The resist film 110 may be formed on the material layer 130. The material layer 130 may include an insulating material (e.g., silicon oxide, silicon nitride), a semiconductor material (e.g., silicon), or a metal (e.g., copper). In some example embodiments, the material layer 130 may have a multilayer structure. The material of the material layer 130 may be different from the material of the substrate 100.

As shown in FIG. 3B, the resist film 110 may be exposed to high-energy rays through a mask 120 after undergoing a prebake process before exposure, and then the resist film 110 may include an exposed portion 111 and an unexposed portion 112.

As shown in FIG. 3C, the exposed resist film 110 may be developed by using a developer (e.g., a developing solution). The unexposed portion 112 may be washed away by the developer, and the exposed portion 111 may remain without being washed away by the developer to define the resist pattern 115.

As shown in FIG. 3D, a material pattern 135 may be formed on a substrate 100 by etching an exposed portion of a material layer 130 using a resist pattern 115 as a mask.

As shown in FIG. 3E, the resist pattern 115 may be removed.

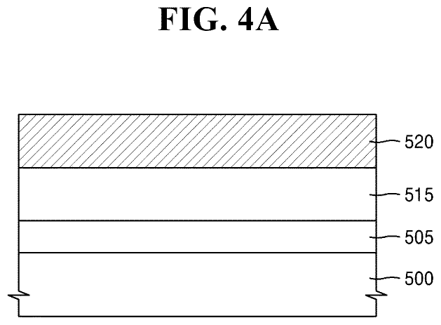

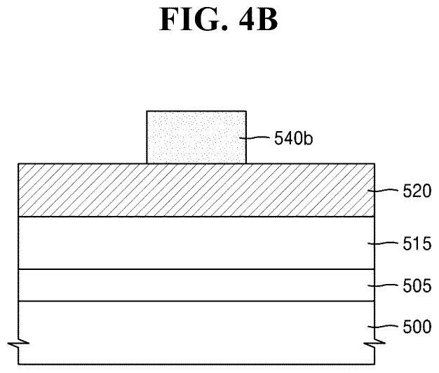

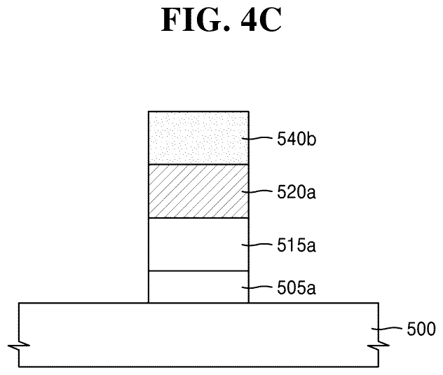

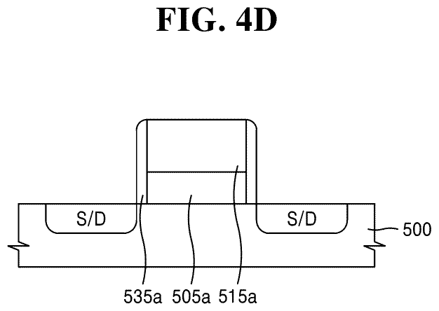

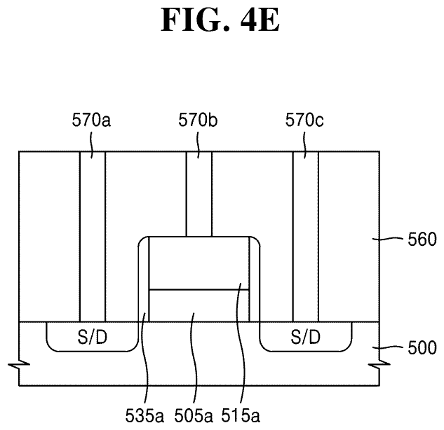

FIGS. 4A, 4B, 4C, 4D, and 4E are side cross-sectional views illustrating a method of forming a semiconductor device according to some example embodiments.

As shown in FIG. 4A, a gate dielectric 505 (e.g., silicon oxide) may be formed on a substrate 500. The substrate 500 may be a semiconductor substrate such as a silicon substrate. A gate layer 515 (e.g., doped polysilicon) may be formed on the gate dielectric 505. A hardmask layer 520 may be formed on the gate layer 515.

As shown in FIG. 4B, a resist pattern 540b may be formed on the hardmask layer 520. A resist pattern 540b may be formed using a resist composition according to some example embodiments. The resist composition may include an organic solvent.

As shown in FIG. 4C, the gate layer 515 and the gate dielectric 505 may be etched to form a hardmask pattern 520a, a gate electrode pattern 515a, and a gate dielectric pattern 505a.

As shown in FIG. 4D, a spacer layer may be formed on the gate electrode pattern 515a and the gate dielectric pattern 505a. The spacer layer may be formed using a deposition process (e.g., chemical vapor deposition (CVD)). The spacer layer may be etched to form a spacers 535a (e.g., silicon nitride) on sidewalls of the gate electrode pattern 515a and the gate dielectric pattern 505a. After forming the spacers 535a, ions may be implanted into the substrate 500 to form source/drain impurity regions S/D.

As shown FIG. 4E, an interlayer insulating layer 560 (e.g., oxide) may be formed on the substrate 500 to cover the gate electrode pattern 515a, the gate dielectric pattern 505a, and the spacers 535a. Then, electrical contacts 570a, 570b, and 570c connected to the gate electrode pattern 515a and the S/D regions may be formed in the interlayer insulating layer 560. The electrical contacts 570a, 570b, and 570c may be formed of a conductive material (e.g., metal). Although not shown, a barrier layer may be formed between sidewalls of the interlayer insulating layer 560 and the electrical contacts 570a, 570b, and 570c.

While FIGS. 4A to 4E illustrate an example of forming a transistor, the inventive concepts are not limited thereto.

A resist composition according to some example embodiments may be used in a patterning process to form other types of semiconductor devices.

The inventive concepts will be described in more detail using the following Examples and Comparative Examples, but the technical scope of the inventive concepts is not limited only to the following Examples.

### EXAMPLES

### Comparative Synthesis Example 1: Synthesis of RM1

### (1) Synthesis of RM1 Precursor

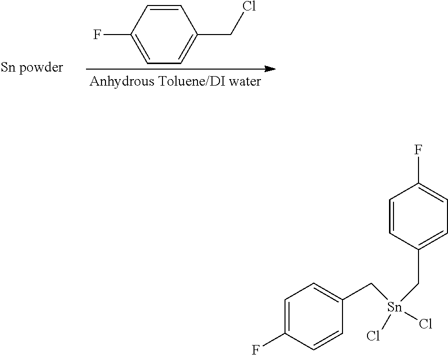 [SMILES: Fc1ccc(CCl)cc1 ; Fc1ccc([CH2][Sn]([Cl])([Cl])[CH2]c2ccc(F)cc2)cc1]

8.2 g (69.2 mmol) of Sn powder and 120 ml of dry toluene were placed in a 250 ml three-necked flask, and the temperature was raised to 90° C. About 1.0 ml of deionized (DI) water was added to the flask, and then 10.0 g (69.2 mmol) of 4-fluorobenzyl chloride was added dropwise thereto over 10 minutes. After performing heating, refluxing, and stirring at 130° C. for 4 hours, the unreacted Sn powder was filtered out by using a Buchner funnel. At the same time, the filtrate was cooled, and 6.5 g (yield 36%) of white crystals (RM1 precursor) were obtained as a product.

### (2) Synthesis of RM1

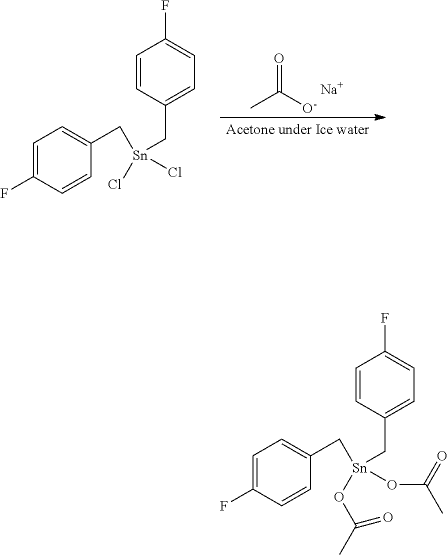

1.5 g (3.7 mmol) of the RM1 precursor and 21.0 ml of dry acetone were placed in a 50 ml single-necked flask, and the temperature was lowered to 0° C. After 0.6 g (7.4 mmol) of sodium acetate was added to the flask, the mixture was stirred for about 12 hours. A NaCl salt produced in the solution was filtered by using a 0.45 μm filter, and the filtrate was concentrated by rotary evaporation and dried under vacuum to obtain RM1 (1.6 g) with a yield of 74%.

¹H-NMR (500 MHz, DMSO-d₆): δ ˜6.9 (8H), ˜2.6 (4H), ˜1.660 (6H)

¹¹⁹Sn-NMR (500 MHz, MC-d₂): δ −251.7

### Comparative Synthesis Example 2: Synthesis of RM2

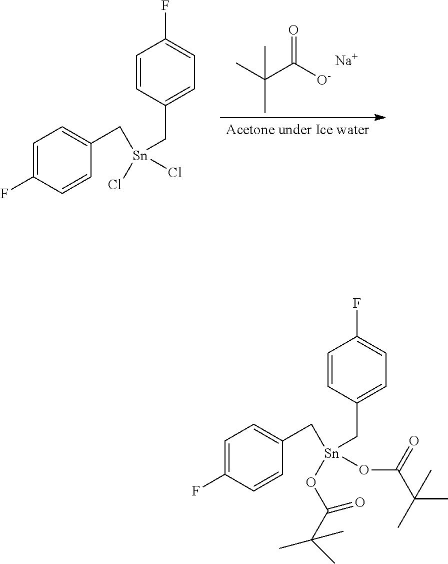

1.5 g (3.7 mmol) of the RM1 precursor and 21.0 ml of dry acetone were placed in a 50 ml single-necked flask, and the temperature was lowered to 0° C. After 0.9 g (7.4 mmol) of sodium pivalate was added to the flask, the mixture was stirred for about 12 hours. A NaCl salt produced in the solution was filtered by using a 0.45 μm filter, and the filtrate was concentrated by rotary evaporation and dried under vacuum to obtain RM2 (1.0 g) with a yield of 42%.

¹H-NMR (500 MHz, DMSO-d₆): δ ˜6.9 (8H), ˜2.6 (4H), ˜0.945 (18H)

¹¹⁹Sn-NMR (500 MHz, MC-d₂): δ −262.1

### Synthesis Example 1: Synthesis of SM1

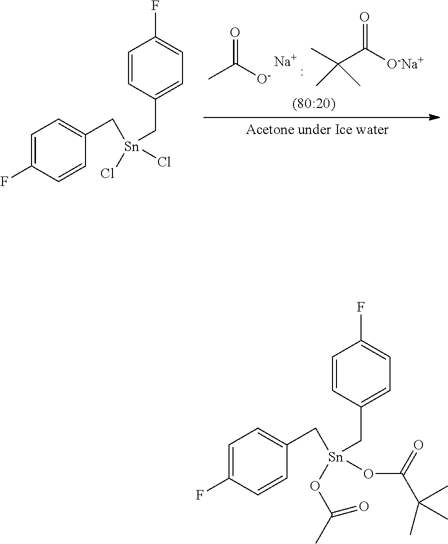

1.5 g (3.7 mmol) of the RM1 precursor and 21.0 ml of dry acetone were placed in a 50 ml single-necked flask, and the temperature was lowered to 0° C. After 0.48 g (5.92 mmol) of sodium acetate and 0.18 g (1.48 mmol) of sodium pivalate were added to the flask, the mixture was stirred for about 12 hours. A NaCl salt produced in the solution was filtered by using a 0.45 μm filter, and the filtrate was concentrated by rotary evaporation and dried under vacuum to obtain SM1 (1.5 g) with a yield of 70%.

¹H-NMR (500 MHz, DMSO-d₆): δ ˜6.9 (8H), ˜2.6 (4H), ˜1.663 (4.44H), ˜0.936 (4.68H)

¹¹⁹Sn-NMR (500 MHz, MC-d₂): δ −252

### Synthesis Example 2: Synthesis of SM2

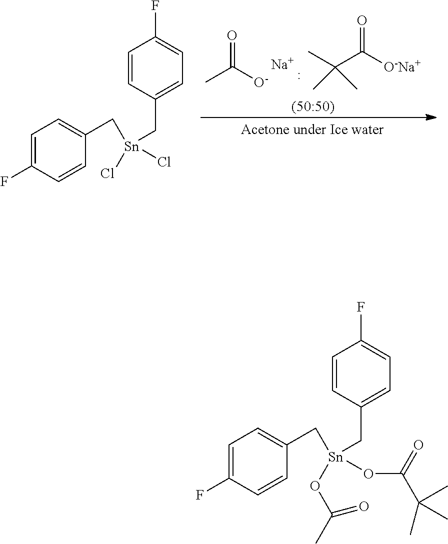

1.5 g (3.7 mmol) of the RM1 precursor and 21.0 ml of dry acetone were placed in a 50 ml single-necked flask, and the temperature was lowered to 0° C. After 0.3 g (3.7 mmol) of sodium acetate and 0.45 g (3.7 mmol) of sodium pivalate were added to the flask, the mixture was stirred for about 12 hours. A NaCl salt produced in the solution was filtered by using a 0.45 μm filter, and the filtrate was concentrated by rotary evaporation and dried under vacuum to obtain SM2 (1.7 g) with a yield of 76%.

¹H-NMR (500 MHz, DMSO-d₆): δ ˜6.9 (8H), ˜2.6 (4H), ˜1.671 (3H), ˜0.941 (9H)

¹¹⁹Sn-NMR (500 MHz, MC-d₂): δ −256

### Synthesis Example 3: Synthesis of SM3

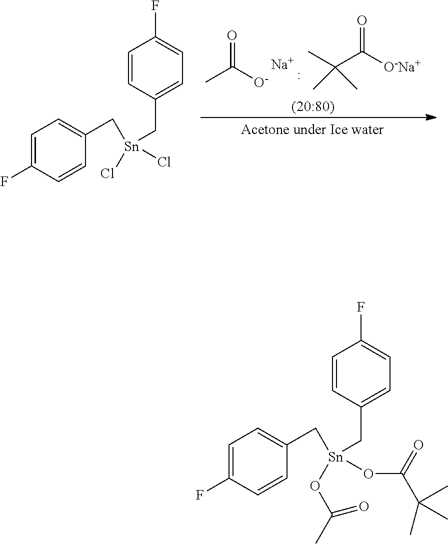

1.5 g (3.7 mmol) of the RM1 precursor and 21.0 ml of dry acetone were placed in a 50 ml single-necked flask, and the temperature was lowered to 0° C. After 0.12 g (1.48 mmol) of sodium acetate and 0.72 g (5.92 mmol) of sodium pivalate were added to the flask, the mixture was stirred for about 12 hours. A NaCl salt produced in the solution was filtered by using a 0.45 μm filter, and the filtrate was concentrated by rotary evaporation and dried under vacuum to obtain SM3 (1.8 g) with a yield of 76%.

¹H-NMR (500 MHz, DMSO-d₆): δ ˜6.9 (8H), ˜2.6 (4H), ˜1.673 (0.84H), ˜0.944 (15.48H)

¹¹⁹Sn-NMR (500 MHz, MC-d₂): δ −260

As a result of ¹H-NMR measurement of Synthesis Examples 1 to 3, it was confirmed that the ratio of acetate:pivalate was 74:26 for SM1, 50:50 for SM2, and 14:86 for SM3. In addition, through ¹¹⁹Sn NMR of Comparative Synthesis Examples 1 and 2 and Synthesis Examples 1 to 3, it was confirmed that SM1, SM2, and SM3 each had different results from RM1 and RM2, and from this, it was confirmed that SM1, SM2, and SM3 were synthesized.

### Evaluation Example 1: Evaluation of Solution Stability

Each of the organometallic compounds synthesized in Comparative Synthesis Examples 1 and 2 and Synthesis Examples 1 to 3 was dissolved in ethyl lactate at 2 wt % to prepare a casting solution. A silicon wafer with a diameter of 4 inches was treated with O₂ plasma for 30 minutes, and then spin-coated with the casting solution at a coating speed of 1500 ppm for 1 minute, followed by performing post application bake (PAB) at 120° C. to manufacture a film having an initial thickness as shown in Table 1 below.

In addition, each of the organometallic compounds synthesized in Comparative Synthesis Examples 1 and 2 and Synthesis Examples 1 to 3 was dissolved in ethyl lactate at 2 wt % to prepare a casting solution, and the casting solution was stored for 1 week to 4 weeks under the same conditions of a temperature of about 20° C. and a humidity of about 35%. A silicon wafer with a diameter of 4 inches was treated with O₂ plasma for 30 minutes, and then spin-coated with the casting solution at a coating speed of 1500 ppm for 1 minute, followed by performing PAB at 120° C. to manufacture a film having an initial thickness as shown in Table 1 below. The respective film specimens manufactured using Comparative Synthesis Examples 1 and 2 and Synthesis Examples 1 to 3, are referred to herein as Comparative Examples 1-1 and 1-2 and Examples 1-1 to 1-3, respectively, and are collectively referred to herein as film examples, manufacturing examples, or the like.

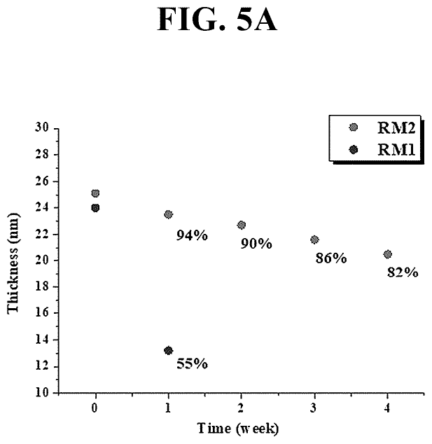

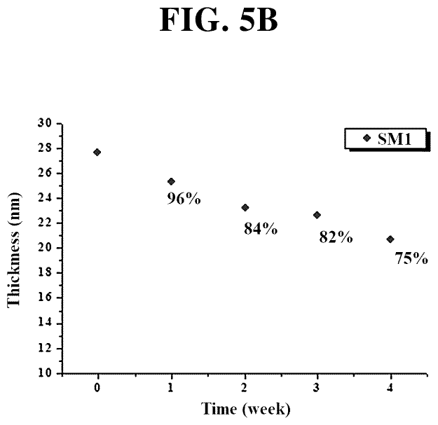

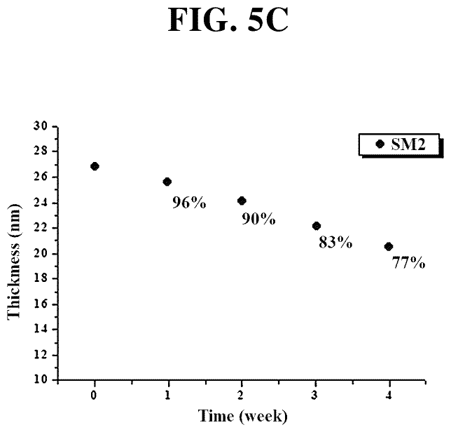

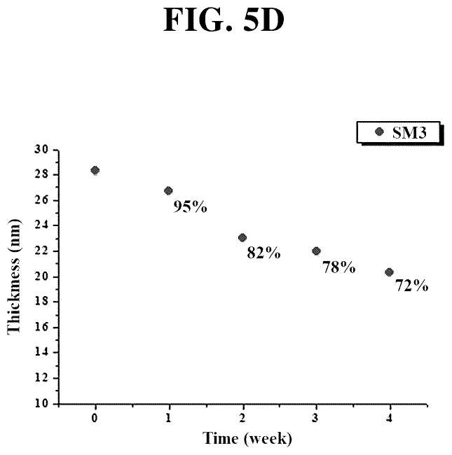

The remaining thickness for each specimen was measured and shown in Table 1 below and FIGS. 5A to 5D.

TABLE 1

| | | Initial | Thickness | | | | Residual film ratio | | | | |
|---|---|---|---|---|---|---|---|---|---|---|---|
| | Organo- | thick- | (nm) | | | | (%) | | | | |
| | metallic | ness | 1 | 2 | 3 | 4 | 1 | 2 | 3 | 4 | |
| | compound | (nm) | week | weeks | weeks | weeks | weeks | weeks | weeks | weeks | Graph |
| Compar- | RM1 | 24.0 | 13.2 | — | — | — | 55 | — | — | — | FIG. |
| ative | | | | | | | | | | | 5A |
| Example | | | | | | | | | | | |
| 1-1 | | | | | | | | | | | |
| Compar- | RM2 | 25.1 | 23.5 | 22.7 | 21.6 | 20.5 | 94 | 90 | 86 | 82 | FIG. |
| ative | | | | | | | | | | | 5A |
| Example | | | | | | | | | | | |
| 1-2 | | | | | | | | | | | |
| Example | SM1 | 27.6 | 25.3 | 23.2 | 22.6 | 20.8 | 96 | 84 | 82 | 75 | FIG. |
| 1-1 | | | | | | | | | | | 5B |
| Example | SM2 | 26.7 | 25.5 | 24.1 | 22.1 | 20.5 | 96 | 90 | 83 | 77 | FIG. |
| 1-2 | | | | | | | | | | | 5C |
| Example | SM3 | 28.2 | 26.7 | 23 | 21.9 | 20.3 | 95 | 82 | 78 | 72 | FIG. |
| 1-3 | | | | | | | | | | | 5D |

Referring to Table 1 and FIGS. 5A to 5D, it was confirmed that for the casting solution of Comparative Example 1-1, when the casting solution had been stored in a solution state for 1 week, and then, a thin film was formed by using the casting solution, only a significantly thinner film was obtained than when a casting solution was used immediately after synthesis of an organometallic compound. On the other hand, it was confirmed that for each of the casting solutions of Examples 1-1 to 1-3, even after storage for 1 week to 4 weeks, a relatively thick film was obtained, and in particular, it was confirmed that a film with a significantly thicker thickness was obtained as compared to Comparative Example 1-1.

For reference, in the case of Comparative Example 1-1, the film thickness and residual film ratio decreased significantly after storage for 1 week in a solution state, so the film thickness and residual film ratio after storage for 2 weeks, 3 weeks, and 4 weeks were not measured.

### Evaluation Example 2: Evaluation of Thin Film Development

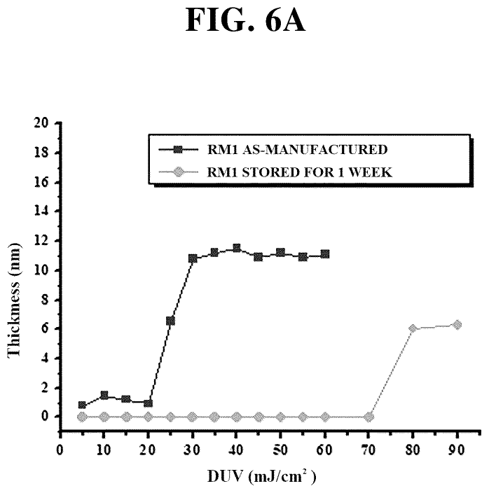

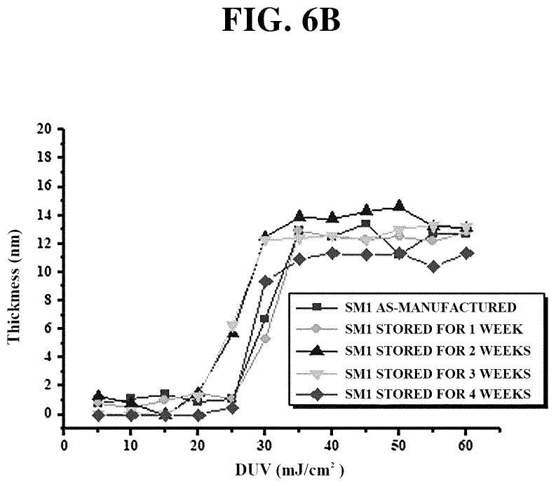

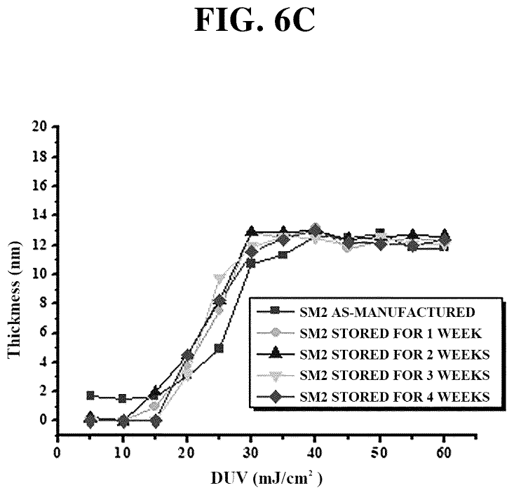

Each of the organometallic compounds synthesized in Comparative Synthesis Example 1 and Synthesis Examples 1 and 2 was dissolved in ethyl lactate at 2 wt % to manufacture a casting solution, and the manufactured casting solution was stored for 1 week to 4 weeks under the same conditions of a temperature of about 20° C. and a humidity of about 35%. A silicon wafer with a diameter of 4 inches was treated with O₂ plasma for 30 minutes, and then spin-coated with each of the casting solution that had been stored in a solution state for a predetermined period of time and the casting solution as-manufactured at a coating speed of 1500 ppm for 1 minute, followed by performing PAB at 120° C. to manufacture a film with an initial thickness of about 20.0 nm. Next, a mask (4 cm×4 cm) having a thickness of 1 cm and perforated rectangular holes (1 cm×1 cm) was placed on the film, and each hole was exposed to deep ultraviolet (DUV) with a wavelength of 254 nm at a dose of 0 mJ/cm² to 60 mJ/cm², and post exposure bake (PEB) was performed at 200° C. for 60 seconds. The dried membrane was immersed in a PGMEA solution (PGMEA (2 wt % A.A.)), in which 2 wt % acetic acid was dissolved, as a developer, at 25° C. for 60 seconds, and then the remaining film thickness was measured. The results are shown in FIGS. 6A to 6C.

Referring to FIGS. 6A to 6C, it was confirmed that RM1 had significantly lower photosensitivity after storage for 1 week, whereas SM1 and SM2 had photosensitivity and solution stability similar to those immediately after synthesis even after storage for 2 weeks or more.

In view of at least the above, some example embodiments of the inventive concepts may provide a resist composition which has improved sensitivity, and provides a pattern with improved resolution and improved solution stability, thereby enabling the formation of a semiconductor device having improved pattern resolutions, thereby enabling miniaturization of semiconductor devices with improved device reliability based on the reduced likelihood of device defects due to reduced likelihood of defects resulting from low pattern resolution.

It should be understood that example embodiments described herein should be considered in a descriptive sense only and not for purposes of limitation. Descriptions of features or aspects within each example embodiment should typically be considered as available for other similar features or aspects in other example embodiments. While some example embodiments have been described with reference to the drawings, it will be understood by those of ordinary skill in the art that various changes in form and details may be made therein without departing from the spirit and scope as defined by the following claims.

What is claimed is:

1. An organometallic compound represented by Formula 1: 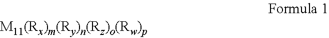
wherein, in Formula 1,
M₁₁ is indium (In), tin (Sn), antimony (Sb), tellurium (Te), thallium (Tl), lead (Pb), bismuth (Bi), or polonium (Po),
Rₓ is *—X₁₁—Y₁₁,
R_{y} is *—X₁₂—Y₁₂,
R_{z} is *—X₁₃—Y₁₃,
R_{w} is *-(L₁) ₐ₁-(R₁)_{b1},
n is an integer from 1 to 4,
m is an integer from 1 to 4,
is an integer from 0 to 4,
p is an integer from 1 to 4,
m+n+o+p is 6 or less,
Rₓ and R_{y} are different from each other,
Formula 1 optionally includes a plurality of Rₓ based on m being greater than 1, the plurality of Rₓ identical to each other,
Formula 1 optionally includes a plurality of R_{y} based on n being greater than 1, the plurality of R_{y} identical to each other,
Formula 1 optionally includes a plurality of R_{z} based on o being greater than 1, the plurality of R_{z} identical to or different from each other,
Formula 1 optionally includes a plurality of R_{w} based on p being greater than 1, the plurality of R_{w} identical to or different from each other,
X₁₁ to X₁₃ are each independently O, OC(═O), C(═O)O, OS(═O), S(═O)O, OS(═O)₂, S(═O)₂O, S, SC(═O), or C(═O)S,
Y₁₁ to Y₁₃ are each independently hydrogen, deuterium, or a linear, branched, or cyclic C₁-C₃₀ monovalent hydrocarbon group optionally including a heteroatom,
L₁ is a linear, branched, or cyclic C₁-C₃₀ divalent hydrocarbon group optionally including a heteroatom,
a1 is an integer from 0 to 4,
R₁ is a linear, branched, or cyclic C₁-C₃₀ monovalent hydrocarbon group optionally including a heteroatom,
b1 is an integer from 1 to 4, wherein Formula 1 optionally includes a plurality of R₁ based on b1 being greater than 1, two adjacent groups among the plurality of R₁ optionally bonded to each other to form a ring, and
* indicates a binding site to a neighboring atom of Formula 1.

2. The organometallic compound of claim 1, wherein, in Formula 1,
M₁₁ is Sn, Sb, Te, or Bi.

3. The organometallic compound of claim 1, wherein, in Formula 1,
wherein n is 1 or 2, m is 1 or 2, o is an integer from 0 to 2, and p is 1 or 2.

4. The organometallic compound of claim 1, wherein, in Formula 1,
n is 1 or 2, m is 1 or 2, o is an integer from 0 to 2, p is 1 or 2, m+n+0+p is 4, and M₁₁ is Sn.

5. The organometallic compound of claim 1, wherein, in Formula 1,
a first bond between M₁₁ and Rₓ is an M₁₁-oxygen single bond or an M₁₁-sulfur single bond,
a second bond between M₁₁ and R_{y} is an M₁₁-oxygen single bond or an M₁₁-sulfur single bond,
a third bond between M₁₁ and R_{z} is an M₁₁-oxygen single bond or an M₁₁-sulfur single bond, and
a fourth bond between M₁₁ and R_{w} is an M₁₁-carbon single bond.

6. The organometallic compound of claim 1, wherein, in Formula 1,
a difference in molecular weight between Rₓ and R_{y} is about 40 g/mol or more.

7. The organometallic compound of claim 1, wherein, in Formula 1,
a light sensitivity of Rₓ is greater than a light sensitivity of R_{y}, and
a moisture sensitivity of Rₓ is greater than a moisture sensitivity of R_{y}.

8. The organometallic compound of claim 1, wherein, in Formula 1,
X₁₁ to X₁₃ are each independently O, OC(═O), C(═O)O, S, SC(═O), or C(═O)S, and
Y₁₁ to Y₁₃ are each independently hydrogen, deuterium, a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group.

9. The organometallic compound of claim 1, wherein, in Formula 1,
L₁ is a single bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group, and
R₁ is a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, a substituted or unsubstituted C₇-C₃₀ arylalkyl group, a substituted or unsubstituted C₁-C₃₀ heteroaryl group, or a substituted or unsubstituted C₂-C₃₀ heteroarylalkyl group.

10. The organometallic compound of claim 1, wherein
the organometallic compound represented by Formula 1 is represented by one of Formulae 1-1 or 1-2: 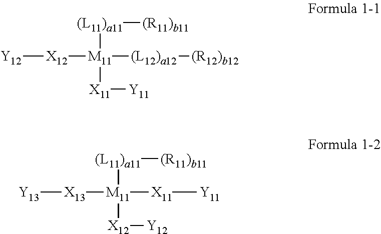
wherein, in Formulae 1-1 and 1-2,
M₁₁ is indium (In), tin (Sn), antimony (Sb), tellurium (Te), thallium (Tl), lead (Pb), bismuth (Bi), or polonium (Po),
X₁₁ to X₁₃ are each independently O, OC(═O), C(═O)O, OS(═O), S(═O)O, OS(═O)₂, S(═O)₂O, S, SC(═O), or C(═O)S,
Y₁₁ to Y₁₃ are each independently hydrogen, deuterium, or a linear, branched, or cyclic C₁-C₃₀ monovalent hydrocarbon group optionally including a heteroatom,
L₁₁ and L₁₂ are each independently a linear, branched, or cyclic C₁-C₃₀ divalent hydrocarbon group optionally including a heteroatom,
a11 and a12 are each independently an integer from 0 to 4,
R₁₁ and R₁₂ are each independently a linear, branched, or cyclic C₁-C₃₀ monovalent hydrocarbon group optionally including a heteroatom, and
b11 and b12 are each independently is an integer from 1 to 4, wherein
Formulae 1-1 and 1-2 each optionally include a plurality of R₁₁ based on b11 being greater than 1, two adjacent groups among the plurality of R₁₁ optionally bonded to each other to form a ring, and
Formula 1-1 optionally includes a plurality of R₁₂ based on b12 being greater than 1, two adjacent groups among the plurality of R₁₂ optionally bonded to each other to form a ring.

11. The organometallic compound of claim 1, wherein
the organometallic compound represented by Formula 1 is selected from Group I:

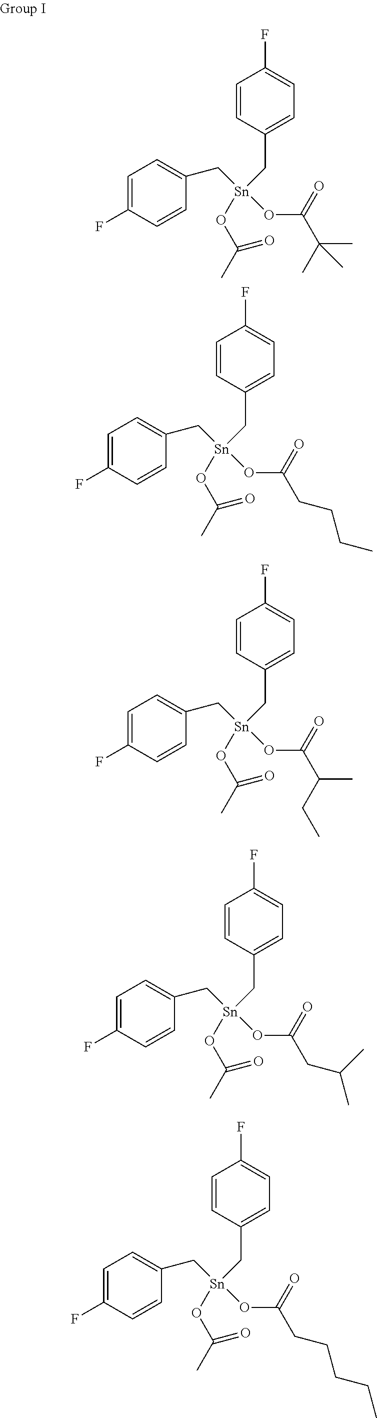

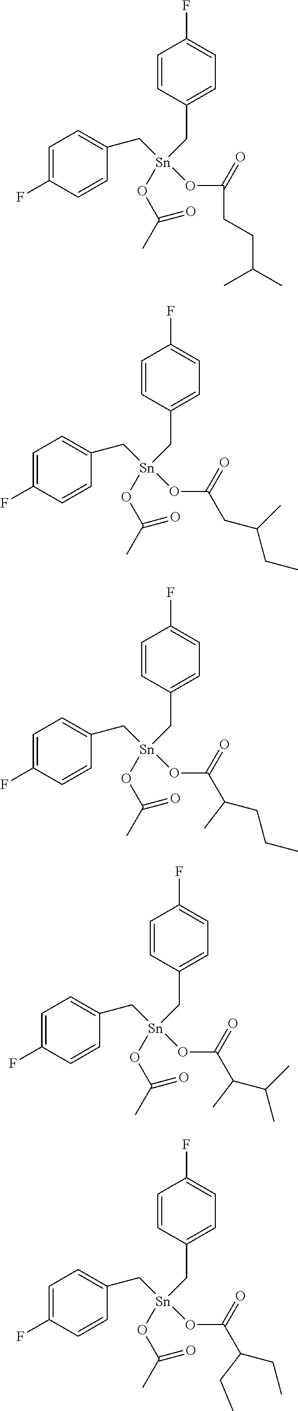

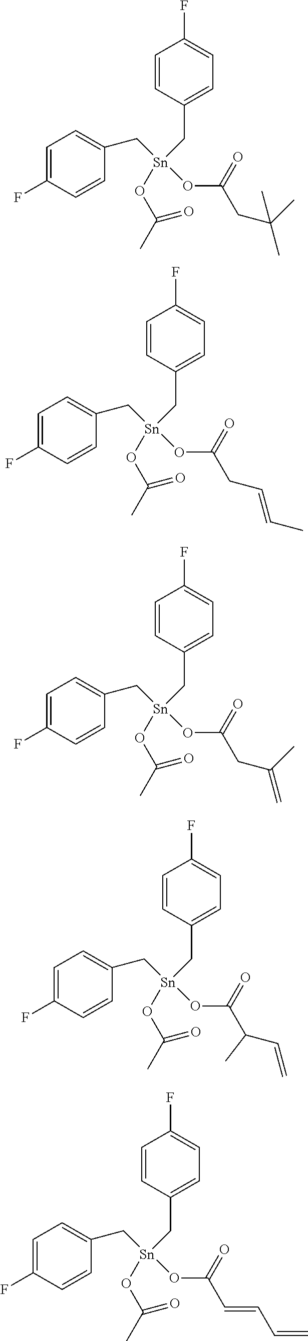

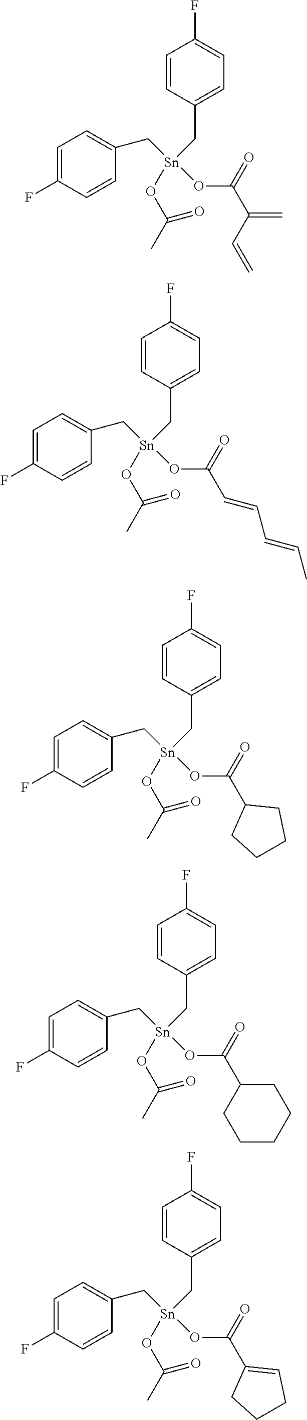

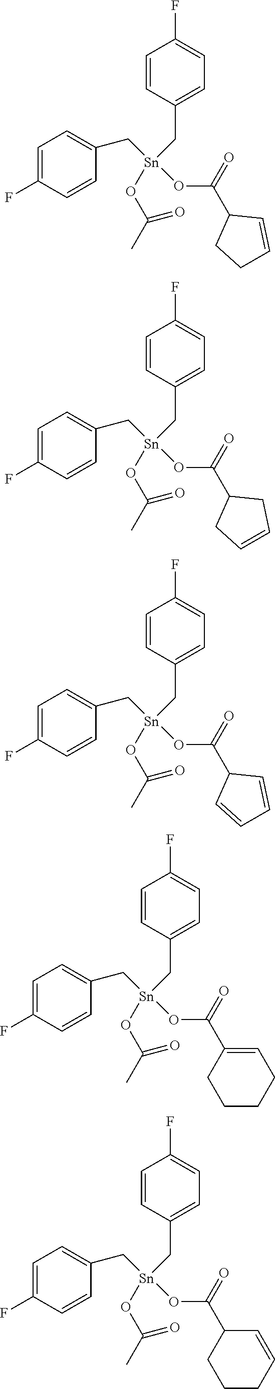 [SMILES: CC(=O)[O][Sn]([CH2]c1ccc(F)cc1)([CH2]c1ccc(F)cc1)[O]C(=O)C1C=CCC1 ; CC(=O)[O][Sn]([CH2]c1ccc(F)cc1)([CH2]c1ccc(F)cc1)[O]C(=O)C1CC=CC1 ; CC(=O)[O][Sn]([CH2]c1ccc(F)cc1)([CH2]c1ccc(F)cc1)[O]C(=O)C1C=CC=C1 ; CC(=O)[O][Sn]([CH2]c1ccc(F)cc1)([CH2]c1ccc(F)cc1)[O]C(=O)C1=CCCCC1 ; CC(=O)[O][Sn]([CH2]c1ccc(F)cc1)([CH2]c1ccc(F)cc1)[O]C(=O)C1C=CCCC1]

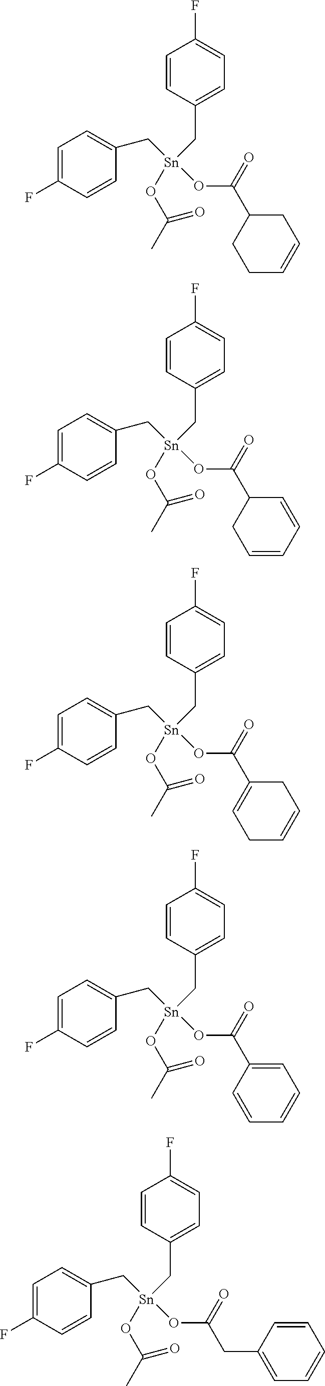 [SMILES: CC(=O)[O][Sn]([CH2]c1ccc(F)cc1)([CH2]c1ccc(F)cc1)[O]C(=O)C1CC=CCC1 ; CC(=O)[O][Sn]([CH2]c1ccc(F)cc1)([CH2]c1ccc(F)cc1)[O]C(=O)C1C=CC=CC1 ; CC(=O)[O][Sn]([CH2]c1ccc(F)cc1)([CH2]c1ccc(F)cc1)[O]C(=O)C1=CCC=CC1 ; CC(=O)[O][Sn]([CH2]c1ccc(F)cc1)([CH2]c1ccc(F)cc1)[O]C(=O)c1ccccc1 ; CC(=O)[O][Sn]([CH2]c1ccc(F)cc1)([CH2]c1ccc(F)cc1)[O]C(=O)Cc1ccccc1]

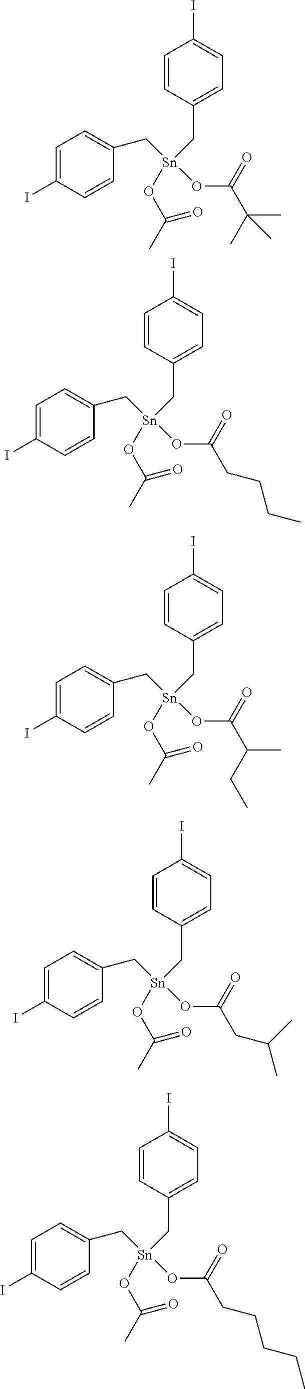

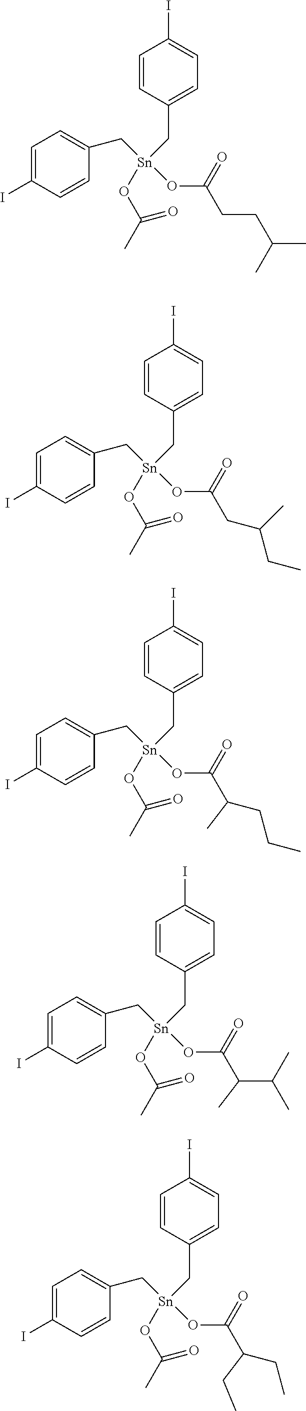 [SMILES: CC(=O)[O][Sn]([CH2]c1ccc(I)cc1)([CH2]c1ccc(I)cc1)[O]C(=O)CCC(C)C ; CCC(C)CC(=O)[O][Sn]([CH2]c1ccc(I)cc1)([CH2]c1ccc(I)cc1)[O]C(C)=O ; CCCC(C)C(=O)[O][Sn]([CH2]c1ccc(I)cc1)([CH2]c1ccc(I)cc1)[O]C(C)=O ; CC(=O)[O][Sn]([CH2]c1ccc(I)cc1)([CH2]c1ccc(I)cc1)[O]C(=O)C(C)C(C)C ; CCC(CC)C(=O)[O][Sn]([CH2]c1ccc(I)cc1)([CH2]c1ccc(I)cc1)[O]C(C)=O]

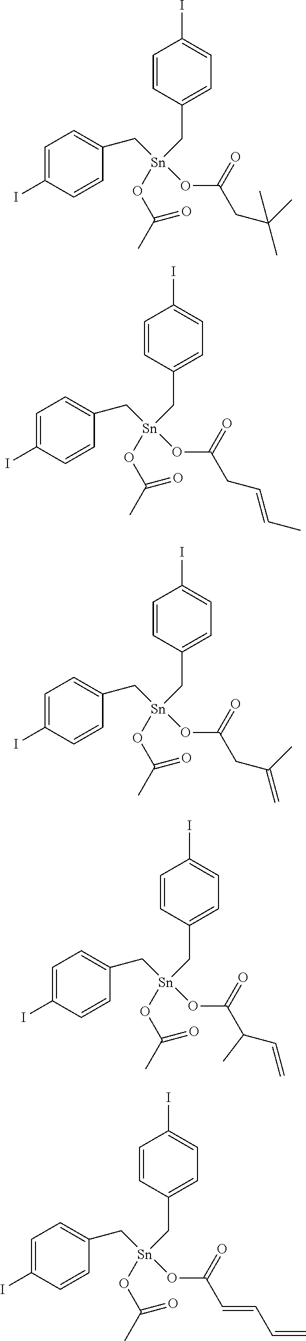

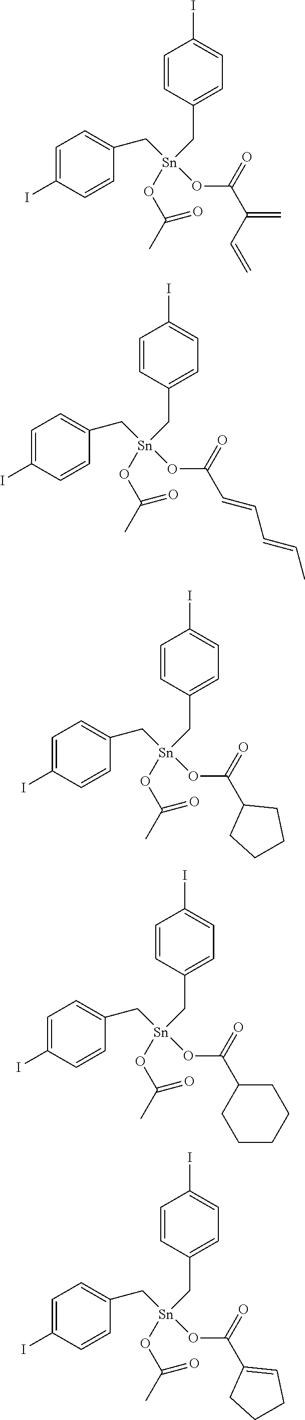

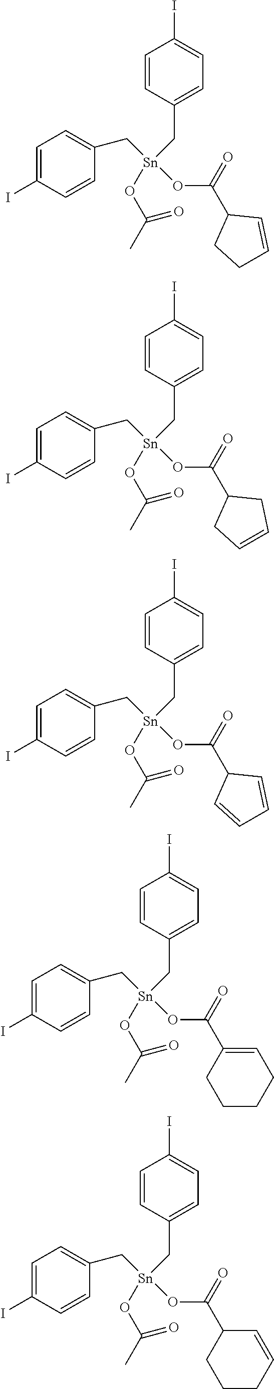 [SMILES: CC(=O)[O][Sn]([CH2]c1ccc(I)cc1)([CH2]c1ccc(I)cc1)[O]C(=O)C1C=CCC1 ; CC(=O)[O][Sn]([CH2]c1ccc(I)cc1)([CH2]c1ccc(I)cc1)[O]C(=O)C1CC=CC1 ; CC(=O)[O][Sn]([CH2]c1ccc(I)cc1)([CH2]c1ccc(I)cc1)[O]C(=O)C1C=CC=C1 ; CC(=O)[O][Sn]([CH2]c1ccc(I)cc1)([CH2]c1ccc(I)cc1)[O]C(=O)C1=CCCCC1 ; CC(=O)[O][Sn]([CH2]c1ccc(I)cc1)([CH2]c1ccc(I)cc1)[O]C(=O)C1C=CCCC1]

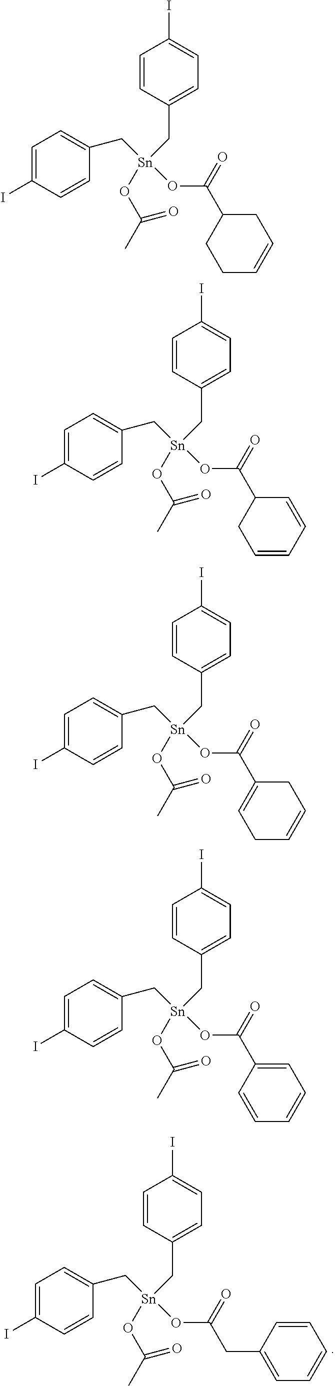

12. A resist composition comprising a first organometallic compound, the first organometallic compound being the organometallic compound of claim 1.

13. The resist composition of claim 12, wherein
the resist composition further comprises at least one of a second organometallic compound represented by Formula 2-1 or a third organometallic compound represented by Formula 2-2,
the first organometallic compound and the second organometallic compound are different from each other,
the first organometallic compound and the third organometallic compound are different from each other, and
the second organometallic compound and the third organometallic compound are different from each other: 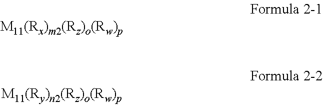
wherein, in Formulae 2-1 and 2-2,
M₁₁ is In, Sn, Sb, Te, Tl, Pb, Bi, or Po,
Rₓ is *—X₁₁—Y₁₁,
R_{y} is *—X₁₂—Y₁₂,
R_{z} is *—X₁₃—Y₁₃,
R_{w} is *-(L₁) ₐ₁-(R₁)_{b1},
n2 is an integer from 2 to 4,
m2 is an integer from 2 to 4,
o is an integer from 0 to 4,
p is an integer from 1 to 4,
m2+o+p is 6 or less,
n2+o+p is 6 or less,
Formula 2-1 optionally includes a plurality of Rₓ based on m2 being greater than 1, the plurality of Rₓ identical to each other,
Formula 2-2 optionally includes a plurality of R_{y} based on n2 being greater than 1, the plurality of R_{y} identical to each other,
Formulae 2-1 and 2-2 each optionally include a plurality of R_{z} based on o being greater than 1, the plurality of R_{z} identical to or different from each other,
Formulae 2-1 and 2-2 each optionally include a plurality of R_{w} based on p being greater than 1, the plurality of R_{w} identical to or different from each other,
X₁₁ to X₁₃ are each independently O, OC(═O), C(═O)O, OS(═O), S(═O)O, OS(═O)₂, S(═O)₂O, S, SC(═O), or C(═O)S,
Y₁₁ to Y₁₃ are each independently hydrogen, deuterium, or a linear, branched, or cyclic C₁-C₃₀ monovalent hydrocarbon group optionally including a heteroatom,
L₁ is a linear, branched, or cyclic C₁-C₃₀ divalent hydrocarbon group optionally including a heteroatom,
a1 is an integer from 0 to 4,
R₁ is a linear, branched, or cyclic C₁-C₃₀ monovalent hydrocarbon group optionally including a heteroatom,
b1 is an integer from 1 to 4, wherein Formulae 2-1 and 2-2 each optionally include a plurality of R₁ based on b1 being greater than 1, two adjacent groups among the plurality of R₁ optionally bonded to each other to form a ring, and
* indicates a binding site to a neighboring atom of Formula 2-1 or Formula 2-2.

14. The resist composition of claim 13, wherein
the resist composition is substantially free of any photoacid generators.

15. The resist composition of claim 13, wherein
the resist composition is substantially free of any compounds having a molecular weight of about 1,000 or more.

16. The resist composition of claim 13, wherein
the resist composition further comprises an organic solvent.

17. The resist composition of claim 16, wherein
the organic solvent is a polar aprotic solvent.

18. A pattern formation method, comprising:
applying the resist composition of claim 13 onto a substrate, to form a resist film;
exposing at least a portion of the resist film to high-energy rays to form an exposed resist film; and
developing the exposed resist film based on using a developer.

19. The pattern formation method of claim 18, wherein
the exposing is performed based on irradiating at least one of ultraviolet rays, deep ultraviolet (DUV) rays, extreme ultraviolet (EUV) rays, X-rays, γ-rays, electron beams (EBs), or α-rays.

20. The pattern formation method of claim 18, wherein
based on the exposing at least the portion of the resist film, the exposed resist film comprises an exposed portion and an unexposed portion, and
the developing the exposed resist film includes removing the unexposed portion.
